(19) United States
(12) Patent Application Publication
(10) Pub. No.: US 2025/0246830 A1
(43) Pub. Date: Jul. 31, 2025

(54) CONNECTOR AND CONNECTOR ASSEMBLY

(71) Applicant: Yamaichi Electronics Co., Ltd., Tokyo (JP)

(72) Inventors: Toshiyasu ITO, Tokyo (JP); Christopher R. COLE, Redwood City, CA (US); Koji KIKUCHI, Tokyo (JP)

(21) Appl. No.: 19/024,834

(22) Filed: Jan. 16, 2025

Related U.S. Application Data
(63) Continuation-in-part of application No. 18/606,603, filed on Mar. 15, 2024.
(60) Provisional application No. 63/626,862, filed on Jan. 30, 2024.

(51) Int. Cl. H01R 12/71; H01R 12/70; H01R 13/02; H01R 13/447; H01R 25/16

(52) U.S. Cl. CPC H01R 12/716; H01R 12/7088; H01R 13/02; H01R 13/447; H01R 25/162

(57) ABSTRACT

Provided is a connector which is mounted on a circuit board and into which a module board of an external module is inserted in a first direction. The circuit board has pads for power supply that are arranged spaced apart from each other in a second direction, and the module board has electrodes for power supply. The connector includes: a connector body into which the module board is inserted; one or more power supply pins accommodated inside the connector body and being in contact with the electrodes for power supply of the module board; and at least one bus bar. The bus bar is connected to the one or more power supply pins and connected to the pads for power supply that are arranged spaced apart from each other in the second direction.

### CROSS-REFERENCE TO RELATED APPLICATIONS

This application is a Continuation-in-Part of U.S. patent application Ser. No. 18/606,603, filed Mar. 15, 2024, which claims the benefit of U.S. Provisional Application No. 63/626,862 filed Jan. 30, 2024, the disclosures of each of which are incorporated herein by reference.

### DESCRIPTION OF RELATED ART

An increase in the number of layers of a printed circuit board (PCB) for routing of high-speed signals may lead to an increase in manufacturing costs or a reduction in reliability and is therefore not preferable. Thus, there is a demand for reducing the total number of layers and reducing the board thickness of a PCB as much as possible.

On the other hand, to transmit high-speed signals (for example, signals of 224 Gbps or higher), it is desirable to increase Line/Space (L/S) of routing as much as possible to reduce an insertion loss.

In view of the above issues, it is preferable to reduce the number of power supply layers of a PCB.

Accordingly, the present disclosure intends to provide a connector and a connector assembly for reducing the number of power supply layers to reduce the total number of layers and reduce the board thickness of a PCB.

### BRIEF SUMMARY

To achieve the above object, the connector and the connector assembly of the present disclosure employ the following solutions.

A connector according to a first aspect of the present disclosure is a connector which is mounted on a circuit board and into which a module board of an external module being inserted in a first direction. The circuit board has a plurality of pads for power supply that are arranged spaced apart from each other in a second direction substantially orthogonal to the first direction, and the module board has a plurality of electrodes for power supply. The connector includes: a connector body into which the module board is inserted; one or a plurality of power supply pins accommodated inside the connector body and being in contact with the plurality of electrodes for power supply of the module board; and at least one bus bar, and the bus bar is connected to the one or plurality of power supply pins and is connected to the plurality of pads for power supply that are arranged spaced apart from each other in the second direction.

Since the bus bar is connected to one or a plurality of power supply pins and connected to the plurality of pads for power supply that are arranged spaced apart from each other in the second direction, the pads for power supply and the power supply pins can be electrically connected to each other via the bus bar.

Further, since the bus bar is connected to one or a plurality of power supply pins and connected to the plurality of pads for power supply that are arranged spaced apart from each other in the second direction, a plurality of pads for power supply that are arranged spaced apart from each other in the second direction can be electrically connected to each other via the bus bar. Thus, even when the power supply layer is omitted from the circuit board, the bus bar can serve as an alternative to the power supply layer. In other words, the power supply layer can be omitted from the circuit board. Further, since the power supply layer can be omitted from the circuit board, the board thickness of the circuit board can be reduced, and the reliability can be improved. Further, since the inner layer wirings for power supply can be omitted from the inner layer of the circuit board, the flexibility in routing of inner layer wirings used for other purposes than power supply (for signaling/for grounding) can be improved.

The connector according to a second aspect of the present disclosure dependent on the first aspect is as follows: the connector body has two second side faces facing each other in the second direction and two third side faces facing each other in a third direction orthogonal to both the first direction and the second direction, the bus bar has a bus bar main face overlapped on the third side face and two bus bar side faces connected to the bus bar main face and overlapped on each of the second side faces, and each of the bus bar side faces is connected to a corresponding pad for power supply of the pads for power supply.

Since the bus bar has the bus bar main face overlapped on at least one third side face and has two bus bar side faces connected to the bus bar main face and overlapped on each second side face, and each bus bar side face is connected to each pad for power supply, a circuit/conductive line/wiring along the side faces of the connector body can be formed by the bus bar.

Further, since the bus bar has the bus bar main face overlapped on the third side faces and has two bus bar side faces connected to the bus bar main face and overlapped on each second side face, the shape of the bus bar can be fitted along the external shape of the connector body, and the external shape of the connector can be minimized.

The connector according to a third aspect of the present disclosure dependent on the second aspect is as follows: the circuit board has a plurality of other-purpose pads used for other purposes than power supply that are aligned in the second direction, and the module board has a plurality of other-purpose electrodes used for other purposes than power supply. The connector further includes a plurality of contact pins accommodated inside the connector body, elongated in the first direction, and being in contact with the other-purpose electrodes of the module board, each of the contact pins has a mount part bonded to the other-purpose pads of the circuit board, a holding part held by interior circumferential walls of the connector body, and a contact part inclined so as to be spaced apart from the interior circumferential walls of the connector body and including a contact area in contact with the module board, and the bus bar main face viewed in the third direction is arranged in a range overlapped neither on the mount part nor on the holding part in the first direction.

Since the bus bar main face viewed in the third direction is arranged in a range overlapped neither on the mount part nor on the holding part in the first direction, it is possible to avoid the bus bar main face being arranged in a range closely adjacent to the contact pins. In other words, the bus bar main face can be arranged in any range as long as it is a range overlapped on a contact part spaced apart from the interior circumferential wall of the connector body or a range where no contact pin is present in the first place. Thus, the bus bar main face is spaced apart from the contact pin, and radiation components of signals transmitted through the contact pin are less likely to be transferred (less likely to be magnetically coupled) to the bus bar main face. This reduces a likelihood of radiation components of signals affecting adjacent channels via the bus bar main face and can reduce crosstalk occurring between these channels.

The connector according to a fourth aspect of the present disclosure dependent on the second aspect or the third aspect is as follows: the number of bus bars is two, and the one or plurality of power supply pins are fixed to two bus bar main faces facing each other in the third direction.

Since the number of bus bars is two, and the one or plurality of power supply pins are fixed to two bus bar main faces facing each other in the third direction, the power supply pins can be firmly fixed to the bus bar. Accordingly, a connector having power supply pins that are less likely to be broken can be provided.

The connector according to a fifth aspect of the present disclosure dependent on the second aspect or the third aspect is as follows: the number of bus bars is one, and the one or plurality of power supply pins are fixed to one bus bar main face.

Since the number of bus bars is one, and the one or plurality of power supply pins are fixed to one bus bar main face, the bus bar having a simple configuration and the power supply pins fixed thereto can be provided. Accordingly, a connector with reduced manufacturing costs can be provided.

The connector according to a sixth aspect of the present disclosure dependent on any one of the second aspect to the fifth aspect is as follows: each of the bus bar side faces of the bus bar has a tab-like side tab, and the side tab is bonded to each of the pads for power supply of the circuit board.

Since each of the bus bar side faces of the bus bar has a tab-like side tab, and the side tab is bonded to each of the pads for power supply of the circuit board, a wider bonding area with the pads for power supply can be ensured. Thus, electric power can be efficiently supplied from the pads for power supply to the bus bar/from the bus bar to the pads for power supply. Further, with a wider bonding area, the bus bar is less likely to be peeled off from the pads for power supply, and as a result, the connector is firmly mounted on the circuit board.

The connector according to a seventh aspect of the present disclosure dependent on one of the second aspect to the sixth aspect, includes at least one cover covering the bus bar.

Since the connector includes at least one cover covering the bus bar, the bus bar is not exposed from the connector in appearance. Thus, the operator is unable to easily touch the bus bar. This can avoid a risk that the operator receives an electric shock due to electric current flowing through the bus bar.

The connector according to an eighth aspect of the present disclosure dependent on the seventh aspect is as follows: the number of covers is the same as the number of bus bars, and the cover has a cover main face overlapped on the bus bar main face and two cover side faces connected to the cover main face and each overlapped on a corresponding bus bar side face of the bus bar side faces.

The number of covers is the same as the number of bus bars, and the cover has a cover main face overlapped on the bus bar main face and two cover side faces connected to the cover main face and each overlapped on a corresponding bus bar side face of the bus bar side faces. For example, when the number of bus bars is one, the bus bar can be covered with one cover, and when the number of bus bars is two, each bus bar can be covered with two covers. Accordingly, the cover can be suitably provided in accordance with the number of bus bars.

The connector according to a ninth aspect of the present disclosure dependent on the eighth aspect is as follows: the number of covers is two, the two covers are arranged facing each other in the third direction, and the cover side faces of one of the covers are each bonded to a corresponding cover side face of the cover side faces of the other of the covers so as to integrate the two covers.

Since the cover side faces of one of the covers are each bonded to a corresponding cover side face of the cover side faces of the other of the covers and thereby the two covers are integrated, the surrounding of the bus bar can be reliably covered with the two covers.

The connector according to a tenth aspect of the present disclosure dependent on the first aspect is as follows: the module board has a plurality of other-purpose electrodes used for other purposes than power supply, and the connector includes a first pin group and a second pin group accommodated inside the connector body, the first pin group and the second pin group each have a plurality of contact pins each elongated in the first direction and being in contact with the other-purpose electrodes of the module board, the first pin group is configured with the plurality of contact pins being aligned in the second direction, the second pin group is configured with the plurality of contact pins being aligned in the second direction, the first pin group and the second pin group are arranged facing each other in a third direction orthogonal to both the first direction and the second direction, the bus bar has a center part arranged between the first pin group and the second pin group and elongated in the second direction and two side parts connected to both ends in the second direction of the center part, and each of the side parts is connected to a corresponding pad for power supply of the pads for power supply.

Since the bus bar has a center part arranged between the first pin group and the second pin group and elongated in the second direction and two side parts connected to both ends in the second direction of the center part, and each of the side parts is connected to a corresponding pad for power supply of the pads for power supply, a circuit/conductive line/wiring extending in the second direction inside the connector body can be formed by the bus bar.

The connector according to an eleventh aspect of the present disclosure dependent on the tenth aspect is as follows: when the connector is mounted on the circuit board, and the module board is inserted into the connector, the center part is located between the first pin group and the second pin group facing each other in the third direction.

Since the center part is located between the first pin group and the second pin group facing each other in the third direction when the connector is mounted on the circuit board and the module board is inserted into the connector, the space formed between the first pin group and the second pin group can be used to install the center part of the bus bar.

A connector assembly according to a twelfth aspect of the present disclosure includes: the connector according to any one of the first aspect to the eleventh aspect; and the circuit board on which the connector is mounted, and the circuit board has the plurality of pads for power supply that are arranged spaced apart from each other in the second direction.

The connector assembly including the connector and the circuit board on which the connector is mounted in which the circuit board has the plurality of pads for power supply that are arranged spaced apart from each other in the second direction can be provided.

The connector assembly according to a thirteenth aspect of the present disclosure dependent on the twelfth aspect is as follows: the circuit board has an inner layer including a plurality of signal layers and one power supply layer, an outermost layer covering the surface of the inner layer, and a plurality of vias, the pads for power supply are connected to the power supply layer of the inner layer through the vias, and the power supply layer is provided at a position closer to the outermost layer than the signal layers.

Since the power supply layer connected to the pads for power supply through the vias is provided at a position closer to the outermost layer than the signal layers, the vias connected to the power supply layer do not penetrate through the signal layer. Thus, the flexibility in routing of signal wirings in the signal layer is improved. If the power supply layer is provided at a position more distant from the outermost layer than the signal layer and the vias penetrated through the signal layer, it would be required to route the signal wirings so as to avoid the vias, and this would limit the region used for the routing.

The connector assembly according to a fourteenth aspect of the present disclosure dependent on the twelfth aspect, further includes the connector according to any one of the first aspect to the eleventh aspect, the connector including a first connector and a second connector, the first connector and the second connector are adjacent to each other in the second direction, and the bus bar of the first connector and the bus bar of the second connector are connected to the pads for power supply provided between and shared by the first connector and the second connector.

Since the first connector and the second connector are adjacent to each other in the second direction, and the bus bar of the first connector and the bus bar of the second connector are connected to the pads for power supply that are provided between and are common to the first connector and the second connector, the electric power supplied to the bus bar of the first connector can be supplied to the second connector (in detail, the power supply pin of the second connector) via the shared pads for power supply and the bus bar of the second connector.

The connector according to a fifteenth aspect of the present disclosure dependent on the first aspect is as follows: the bus bar is indirectly connected to the one or plurality of power supply pins.

Since the bus bar is indirectly connected to the one or plurality of power supply pins, the bus bar and the power supply pins are not required to be directly connected to each other. This increases flexibility in design of the bus bar and/or the power supply pins.

A connector assembly according to a sixteenth aspect of the present disclosure includes: the connector according to the fifteenth aspect; and the circuit board on which the connector is mounted, the one or plurality of power supply pins are connected to pads provided on the circuit board, and the bus bar is connected to the pads to which the one or plurality of power supply pins are connected.

Since the one or plurality of power supply pins are connected to the pad provided on the circuit board, and the bus bar is connected to the pad to which the one or plurality of power supply pins are connected, the bus bar and the power supply pins can be electrically connected to each other via the pad provided on the circuit board.

Further, the shape of each power supply pin is not required to be a special shape in order to be adapted to the shape of the bus bar and, for example, can be fitted to the shape of other contact pins (the signaling pin or the grounding pin). In other words, it is not required to differentiate the shape of the power supply pin from the shape of other contact pins. This makes it possible to commonize the components and reduce manufacturing costs of the connector assembly.

### BRIEF DESCRIPTION OF THE SEVERAL VIEWS OF THE DRAWINGS

FIG. 1 is a perspective view of a connector assembly.

FIG. 2 is a perspective view illustrating a state where optical modules are attached to connectors of the connector assembly illustrated in FIG. 1.

FIG. 3 is a perspective view of a connector according to a first embodiment.

FIG. 4 is a perspective view of the connector with covers being disassembled.

FIG. 5 is a perspective view of the connector (the covers omitted).

FIG. 6 is a perspective view of the connector illustrated in FIG. 5 when viewed from the bottom face.

FIG. 7 is an exploded perspective view of the connector (the covers omitted).

FIG. 8 is a perspective view of the connector disassembled into a connector body and bus bars (the covers omitted).

FIG. 9 is a perspective view of the bus bars before power supply pins are attached.

FIG. 10 is an exploded perspective view of the bus bar before the power supply pins are attached (in which only one of the bus bars is displayed).

FIG. 11 is a perspective view of the bus bar after the power supply pins are attached (in which only one of the bus bars is displayed).

FIG. 12 is an enlarged view of a portion near crimping protrusions of a power supply pin and crimping holes of the bus bar (before the power supply pin is crimped).

FIG. 13 is an enlarged view of the portion near the crimping protrusions of the power supply pin and the crimping holes of the bus bar (after the power supply pin is crimped).

FIG. 14 is a perspective view of a circuit board.

FIG. 15 is a partial enlarged view of the connector assembly.

FIG. 16 is a perspective view of the connector illustrated in FIG. 15 (the connector body and the covers omitted).

FIG. 17A is a table related to a layer configuration of the circuit board.

FIG. 17B is a table related to the layer configuration of the circuit board (continuation of FIG. 17A).

FIG. 18 is a perspective view of a circuit board according to Modified example 1.

FIG. 19 is a partial enlarged view of the circuit board illustrated in FIG. 18.

FIG. 20 is a perspective view of the connector mounted on the circuit board illustrated in FIG. 19 (the connector body and the covers omitted).

FIG. 21 is a perspective view of a bus bar according to Modified example 2.

FIG. 22 is a side view of a connector assembly according to Modified example 3 (the covers omitted).

FIG. 23 is a sectional view taken along the section line XXIII-XXIII illustrated in FIG. 22.

FIG. 24 represents a simulation result indicating improvement against crosstalk.

FIG. 25 is a perspective view of a connector according to a second embodiment.

FIG. 26 is a perspective view of the connector with the covers being disassembled.

FIG. 27 is an exploded perspective view of the connector (the covers omitted).

FIG. 28 is an exploded perspective view of a bus bar before power supply pins are attached.

FIG. 29 is a perspective view of the bus bar after the power supply pins are attached.

FIG. 30 is a perspective view of a connector according to a third embodiment.

FIG. 31 is a sectional view taken along the section line XXXI-XXXI illustrated in FIG. 30 (a cross section passing through the power supply pins).

FIG. 32 is an exploded perspective view of the connector according to the third embodiment.

FIG. 33 is an exploded perspective view of a bus bar before power supply pins are attached.

FIG. 34 is a perspective view of a connector according to a fourth embodiment.

FIG. 35 is a perspective view of the connector with the cover being omitted.

FIG. 36 is a sectional view taken along a section line XXXVI-XXXVI illustrated in FIG. 34.

FIG. 37 is a diagram of a circuit board on which the connector according to the fourth embodiment is mounted when viewed from the first direction.

### DETAILED DESCRIPTION

### First Embodiment

The first embodiment of the present disclosure will be described.

### Connector Assembly

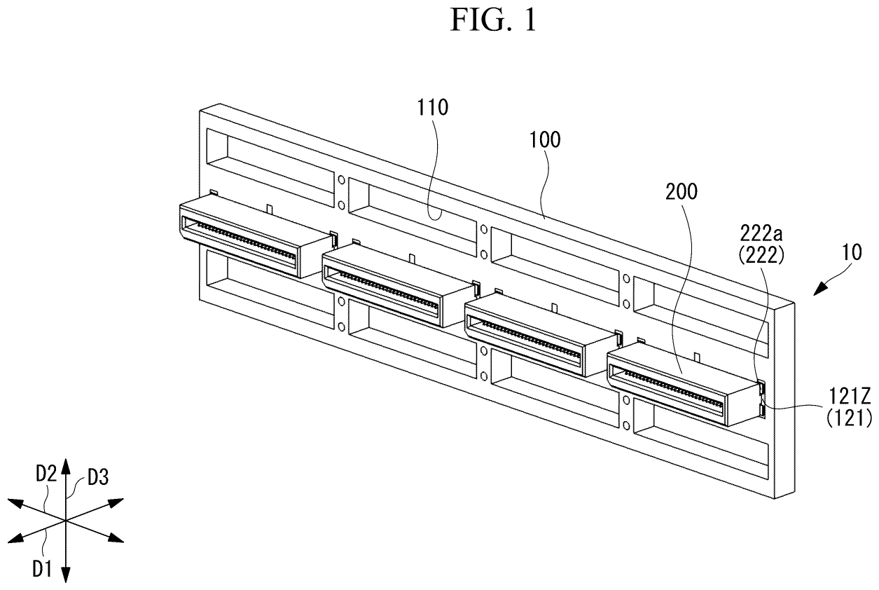

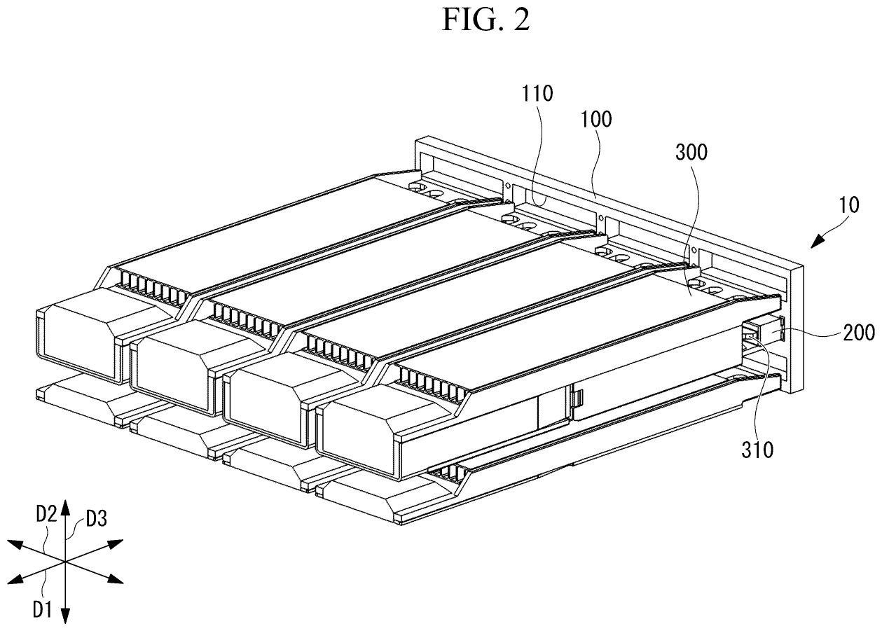

As illustrated in FIG. 1 and FIG. 2, a connector assembly 10 includes a printed circuit board 100 (hereafter, referred to as a “circuit board 100”) and a plurality of connectors 200.

The connectors 200 are mounted on (fixed to) the front face of the circuit board 100. Note that an ASIC is provided on the back face of the circuit board 100.

Optical modules 300 (external module) each having a module board 310 are attached to the connector assembly 10. The module board 310 is inserted into a slot 211 of a connector 200.

The direction in which the module board 310 is inserted into the connector 200 and the direction in which the module board 310 is extracted from the connector 200 are defined as “first direction D1”. The direction orthogonal to “first direction D1” is defined as “second direction D2”. The direction orthogonal to both the first direction D1 and the second direction D2 is defined as “third direction D3”.

As illustrated in FIG. 1 and FIG. 2, the first direction D1 matches the depth direction of the connector assembly 10. The second direction D2 matches the width direction of the connector assembly 10. The third direction D3 matches the height direction of the connector assembly 10. However, these directions are mere examples defined for the purpose of illustration and are not intended to limit the actual attitude or position of the connector assembly 10.

Vent openings 110 are formed in the circuit board 100, and the number of vent openings 110 corresponds to the number of connectors 200. The vent openings 110 are openings for guiding cooling air that has passed through heat sinks of optical modules 300 to the back face of the circuit board 100.

### Connector

The connector 200 is a device for relaying the circuit board 100 to the module board 310 or a device for electrically connecting the circuit board 100 and the module board 310 to each other.

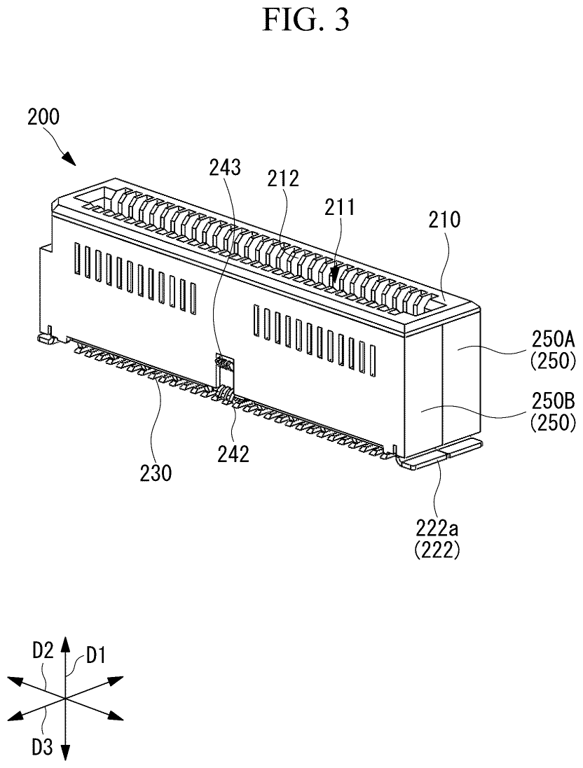

As illustrated in FIG. 3, the connector 200 is substantially rectangular parallelepiped-shaped as a whole.

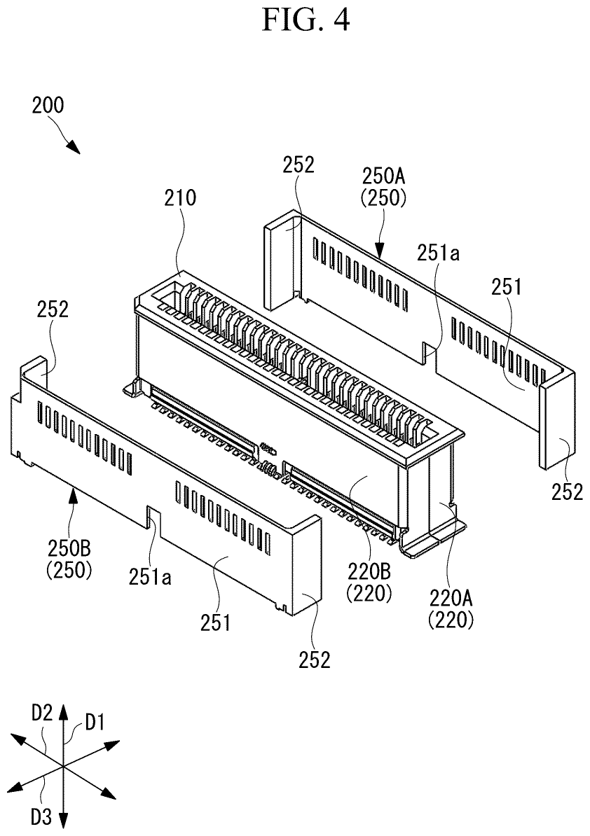

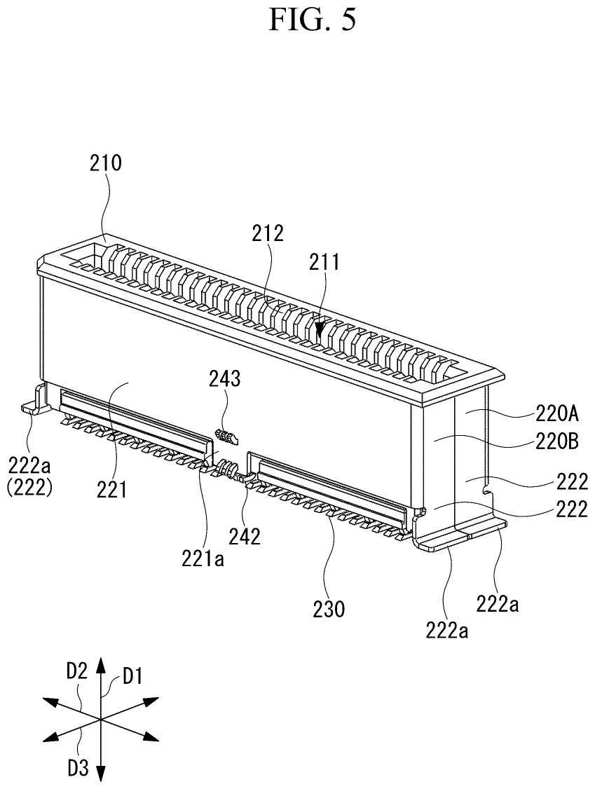

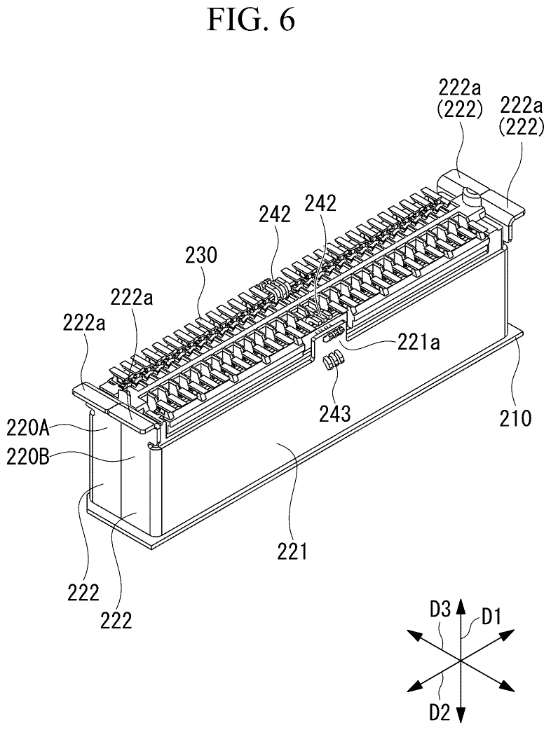

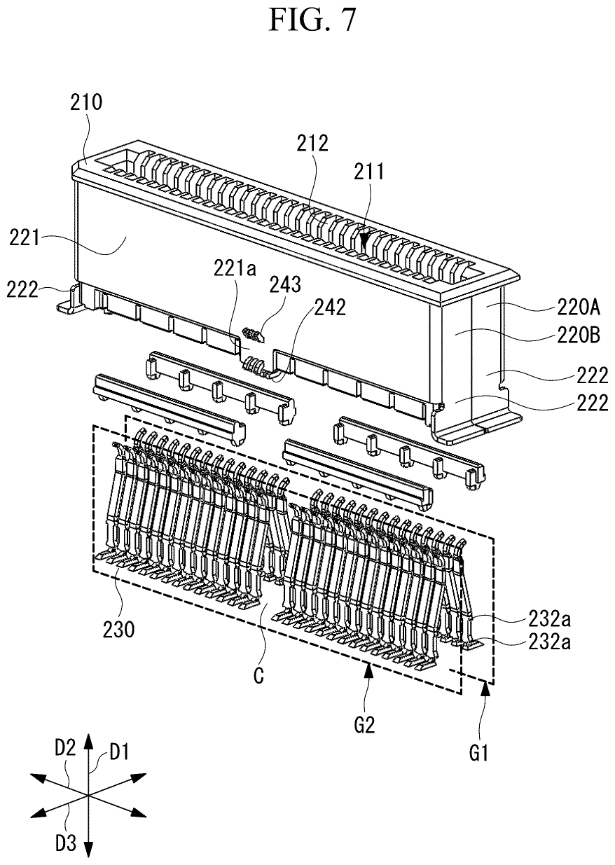

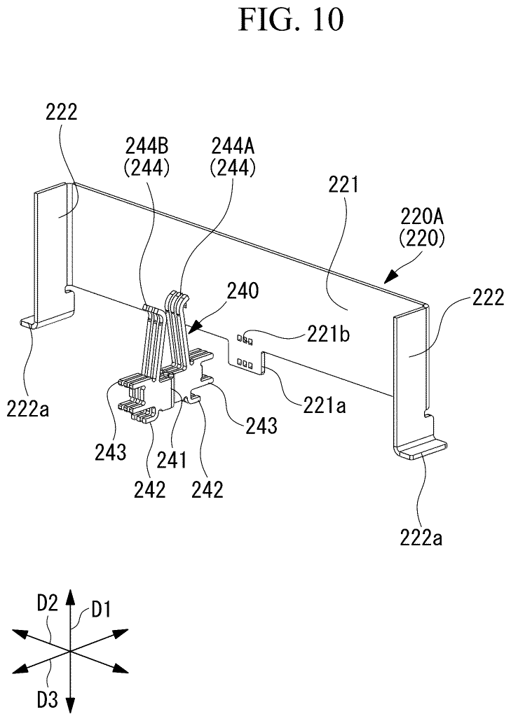

As illustrated in FIG. 3, FIG. 4, FIG. 5, FIG. 6, FIG. 7, and FIG. 10, the connector 200 includes a connector body 210, bus bars 220, a plurality of contact pins 230, a plurality of power supply pins 240, and covers 250.

The connector body 210 is a substantially rectangular parallelepiped-shaped component.

The connector body 210 is formed of an insulating material (for example, a resin).

A slot 211 penetrating in the first direction D1 is formed in the central part of the connector body 210. A module board 310 is inserted into the slot 211.

A plurality of slits 212 each extending in the first direction D1 are formed in the inner circumferential wall of the connector body 210 (the interior circumferential wall, the circumferential wall defining the slot 211). The contact pins 230 are press-fitted into these slits 212, respectively. Accordingly, the contact pins 230 are held by the connector body 210.

The bus bars 220 are attached to the outer circumferential wall (exterior circumferential wall)/side face/surrounding of the connector body 210.

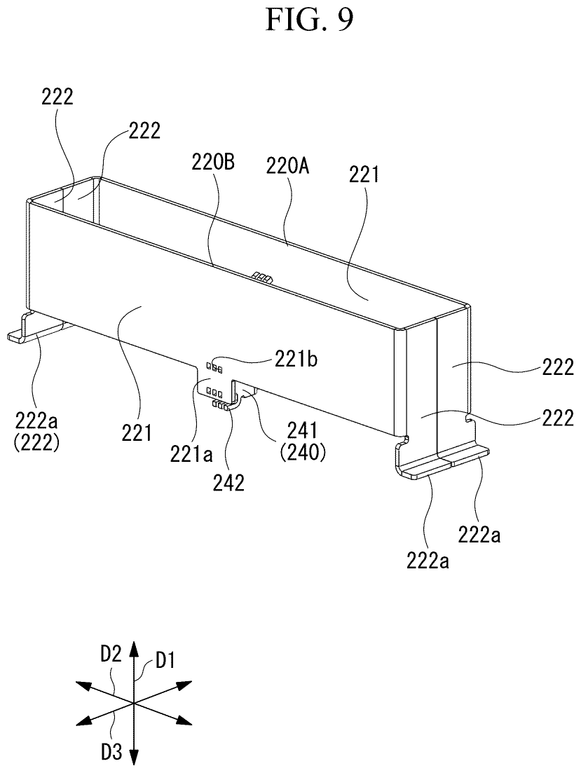

As illustrated in FIG. 9, the bus bars 220 include a first bus bar 220A and a second bus bar 220B.

The first bus bar 220A and the second bus bar 220B have substantially symmetrical shapes with respect to a plane orthogonal to the first direction D1 and are arranged so as to face each other in the third direction D3. In the following, the first bus bar 220A will be described as an example, and description of the second bus bar 220B will be omitted.

As illustrated in FIG. 10, the first bus bar 220A is a substantially U-shaped component.

The first bus bar 220A is formed of a highly electrically conductive material (for example, a metal). Specifically, the first bus bar 220A is formed of a copper-based material with plating (for example, nickel/gold plating) applied thereto.

The first bus bar 220A has one bus bar main face 221 and two bus bar side faces 222.

The bus bar main face 221 is a plate-like face overlapped on a face of the connector body 210 (one of the faces) that the bus bar main face 221 faces in the third direction D3 (see FIG. 5 and the like).

The bus bar side faces 222 are connected to side edges in the second direction D2 of the bus bar main face 221. Each of the bus bar side faces 222 is a plate-like face overlapped on each face of the connector body 210 that each of the bus bar side faces 222 face in the second direction D2 (see FIG. 5 and the like). The side face 222 of one bus bar and the side face 222 of the other bus bar are arranged so as to face each other in the second direction D2. Accordingly, the first bus bar 220A is substantially U-shaped. Thus, the first bus bar 220A is substantially U-shaped along the external shape of the substantially rectangular parallelepiped-shaped connector body 210, and this can minimize the external shape of the connector 200.

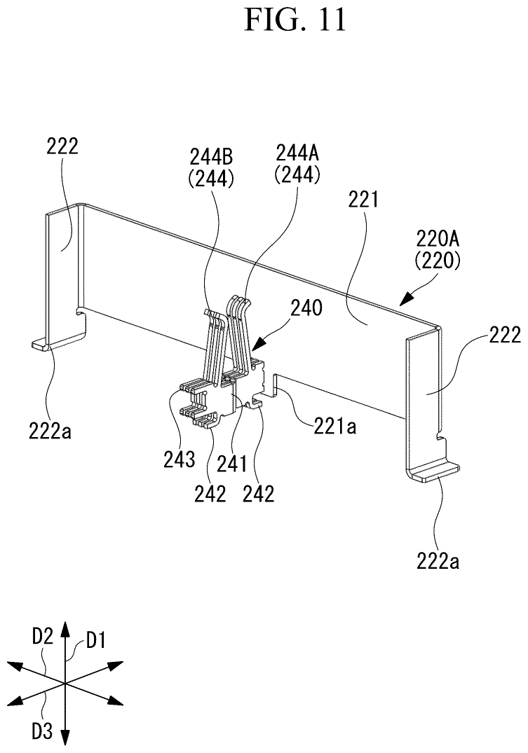

As illustrated in FIG. 9, FIG. 10, and FIG. 11, an expanded part 221a extending in the first direction D1 is provided on an edge of the bus bar main face 221 facing the circuit board 100 when the connector 200 is mounted on the circuit board 100. A plurality of crimping holes 221b are formed in the expanded part 221a. Crimping protrusions 243 of the power supply pin 240 are inserted into these crimping holes 221b, respectively.

Side tabs 222a each extending in the first direction D1 and then bent to be opened outward in the second direction D2 are provided on edges of respective bus bar side faces 222 that face the circuit board 100 when the connector 200 is mounted on the circuit board 100. These side tabs 222a are bonded (for example, connected by soldering) to pads for power supply of the circuit board 100.

As illustrated in FIG. 7, each of the plurality of contact pins 230 is a long, thin component elongated in the first direction D1.

Each contact pin 230 is formed of a highly electrically conductive and elastic material (for example, a metal). Specifically, each contact pin 230 is formed of a copper-based material with plating (for example, nickel/gold plating) applied thereto.

The contact pins 230 include signaling pins for transmitting signals (high-speed signals and low-speed signals) and grounding pins serving as a reference potential, but the contact pins 230 do not include pins for power supply.

A plurality of protrusions 232a are provided on the contact pin 230. Once these protrusions 232a engage into the slits 212 formed in the connector body 210, the contact pins 230 are held by the slits 212 (the connector body 210).

The plurality of contact pins 230 are formed of two groups (a first group G1 and a second group G2). In each group, the plurality of contact pins 230 are aligned with spacings (at a predetermined pitch) in the second direction D2. A clearance C for arranging the power supply pin 240 is provided (a wider spacing than the predetermined pitch is set) between the contact pins 230 located at the central part in the second direction D2. The first group G1 and the second group G2 are arranged so as to face each other in the third direction D3. However, each contact pin 230 included in the first group G1 and each contact pin 230 included in the second group G2 are shifted by a half pitch (half of the predetermined pitch) in the second direction D2. The module board 310 of the optical module 300 is inserted into the clearance between the first group G1 and the second group G2. Each contact pin 230 included in each group then comes into contact with other-purpose electrodes used for other purposes than power supply of the inserted module board 310 in a one-to-one manner. The other-purpose electrodes include signaling electrodes for transmitting signals (high-speed signals and low-speed signals) and grounding electrodes serving as the reference potential.

As illustrated in FIG. 10 and FIG. 11, the power supply pin 240 is a component having a base 241, a plurality of mount parts 242, a plurality of crimping protrusions 243, and a plurality of pin parts 244. The base 241, the plurality of mount parts 242, the plurality of crimping protrusions 243, and the plurality of pin parts 244 are integrally formed of a single member, for example.

Each power supply pin 240 is formed of a highly electrically conductive and elastic material (for example, a metal). Specifically, the power supply pin 240 is formed of a copper-based material with plating (for example, nickel/gold plating) applied thereto.

The base 241 is a plate-like portion having its thickness direction in the second direction D2.

Each mount part 242 is a portion extending in the first direction D1 from an edge of the base 241 and then bent to be opened outward in the third direction D3, the edge of the base 241 facing the circuit board 100 when the connector 200 is mounted on the circuit board 100. These mount parts 242 are bonded (for example, connected by soldering) to pads for power supply of the circuit board 100.

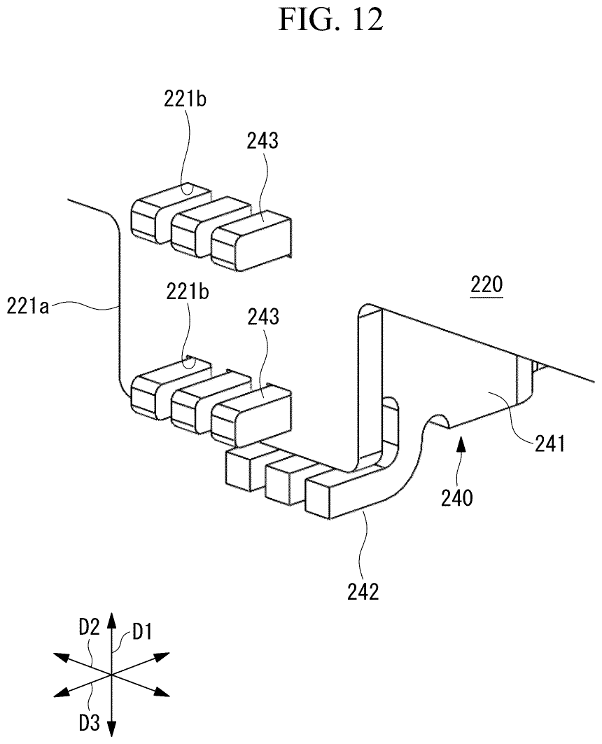

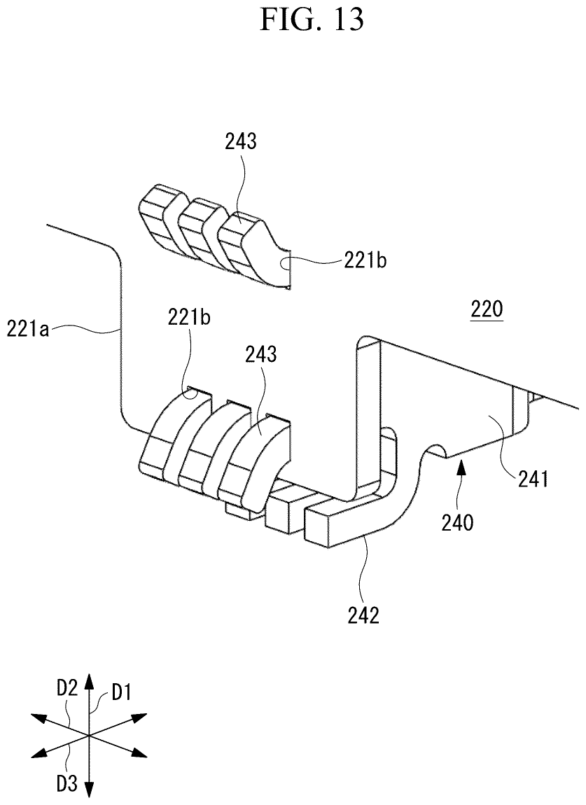

Each crimping protrusion 243 is a portion protruding outward from a side edge in the third direction D3 of the base 241. Two crimping protrusions 243 are provided on each side edge of the base 241. As illustrated in FIG. 12 and FIG. 13, these crimping protrusions 243 are inserted into the crimping holes 221b of the first bus bar 220A and the crimping holes 221b of the second bus bar 220B. The crimping protrusion 243 inserted into the crimping hole 221b is crimped by bending a portion protruding out of the crimping hole 221b. Accordingly, the power supply pins 240 are fixed to the first bus bar 220A and the second bus bar 220B. At the same time, the power supply pins 240 are electrically connected to the first bus bar 220A and the second bus bar 220B.

As illustrated in FIG. 10 and FIG. 11, each pin part 244 is a long, thin portion elongated in the first direction D1 extending in the first direction D1 from an edge of the base 241 facing the slot 211 (the edge located opposite to the edge of the base 241 facing the circuit board 100 when the connector 200 is mounted on the circuit board 100/the edge facing the module board 310 side when the module board 310 is inserted into the connector 200). For example, the pin part 244 has a shape similar to the shape of the contact pin 230. Two pin parts 244 are provided on one base 241. A first pin part 244A and a second pin part 244B are arranged so as to face each other in the third direction D3 while being shifted from each other in the second direction D2. Because the two pin parts 244 shifted in the second direction D2 are provided on one base 241, the portion of the base 241 where the first pin part 244A is provided and the portion of the base 241 where the second pin part 244B is provided are shifted from each other in the second direction D2, and these portions are connected smoothly to each other.

The plurality of (for example, three) power supply pins 240 configured as described above are overlapped to configure the group of power supply pins 240. Such a group of power supply pins 240 is arranged in the clearance C provided between the contact pins 230 of the first group G1 and the clearance C provided between the contact pins 230 of the second group G2. In this state, each pin part 244 of each power supply pin 240 is arranged to be continuous to the contact pins 230 aligned in the second direction D2.

The module board 310 of the optical module 300 is inserted into the clearance between the set of the plurality of first pin parts 244A and the set of the plurality of second pin parts 244B where both the sets are arranged so as to face each other in the third direction D3. Each pin part 244 then comes into contact with the electrodes for power supply of the inserted module board 310. However, respective pin parts 244 are not required to correspond to electrodes for power supply in a one-to-one manner, and it is at least required that one or more pin parts 244 be in contact with one electrode for power supply.

As illustrated in FIG. 3 and FIG. 4, the covers 250 include a first cover 250A and a second cover 250B.

The first cover 250A and the second cover 250B have substantially symmetrical shapes with respect to a plane orthogonal to the first direction D1 and are arranged so as to face each other in the third direction D3. In the following, the first cover 250A will be described as an example, and description of the second cover 250B will be omitted.

The first cover 250A is a substantially U-shaped component.

The first cover 250A is formed of an insulating material (for example, a resin).

The first cover 250A has one cover main face 251 and two cover side faces 252.

The cover main face 251 is a plate-like face overlapped on the bus bar main face 221 of the first bus bar 220A. A cutout 251a for avoiding interference with the crimping protrusions 243 of the power supply pin 240 is formed in the cover main face 251.

The cover side faces 252 are connected to side edges in the second direction D2 of the cover main face 251. Each cover side face 252 is a plate-like face overlapped on each bus bar side face 222 of the first bus bar 220A. One cover side face 252 and the other cover side face 252 are arranged so as to face each other in the second direction D2. Accordingly, the first cover 250A is substantially U-shaped.

The first cover 250A and the second cover 250B are attached so as to interpose the connector body 210 with the bus bars 220 being attached from both sides in the third direction D3. In this state, an edge of each cover side face 252 of the first cover 250A and an edge of each cover side face 252 of the second cover 250B are bonded to each other. For example, the bonding is performed by ultrasonic fusion.

In the connector 200 with the covers 250 being attached, the bus bars 220 (except for the side tabs 222a) are covered with the covers 250. Thus, the operator is unable to easily touch the bus bars 220. This avoids a risk that the operator receives an electric shock due to electric current flowing through the bus bars 220, thereby ensuring safety.

### Assembly of Connector

The connector 200 is assembled as follows.

First, as illustrated in FIG. 10 and FIG. 11, a plurality of power supply pins 240 are attached to the first bus bar 220A. Next, as illustrated in FIG. 9, the plurality of power supply pins 240 attached to the first bus bar 220A are attached to the second bus bar 220B. Accordingly, the first bus bar 220A and the second bus bar 220B arranged so as to face each other in the third direction D3 are connected by the power supply pins 240. In other words, the first bus bar 220A, the second bus bar 220B, and the power supply pins 240 form a single assembly or are integrated.

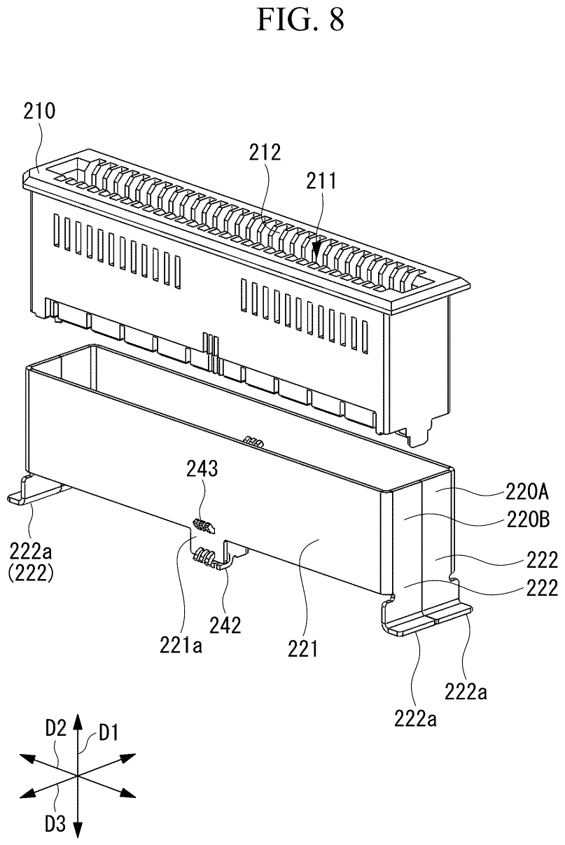

Next, the above assembly is attached to the connector body 210. Specifically, as illustrated in FIG. 8, the assembly is inserted from the bottom face of the connector body 210 (the face facing the circuit board 100 when the connector 200 is mounted on the circuit board 100). Accordingly, the side faces (surrounding) of the connector body 210 are covered with the bus bars 220, and the pin parts 244 of the power supply pins 240 are accommodated inside the connector body 210.

Next, a plurality of contact pins 230 are attached to the connector body 210. Specifically, as illustrated in FIG. 7, each contact pin 230 is inserted into each slit 212 from the bottom face of the connector body 210. At this time, the protrusions 232a of the contact pins 230 engage into the slits 212, and thereby the contact pins 230 are held by the connector body 210.

Next, as illustrated in FIG. 4 and FIG. 3, the first cover 250A and the second cover 250B are attached to interpose the connector body 210 from both sides in the third direction D3. The edge of each cover side face 252 of the first cover 250A and the edge of each cover side face 252 of the second cover 250B are then bonded to integrate the first cover 250A and the second cover 250B.

### Flow of Electric Current

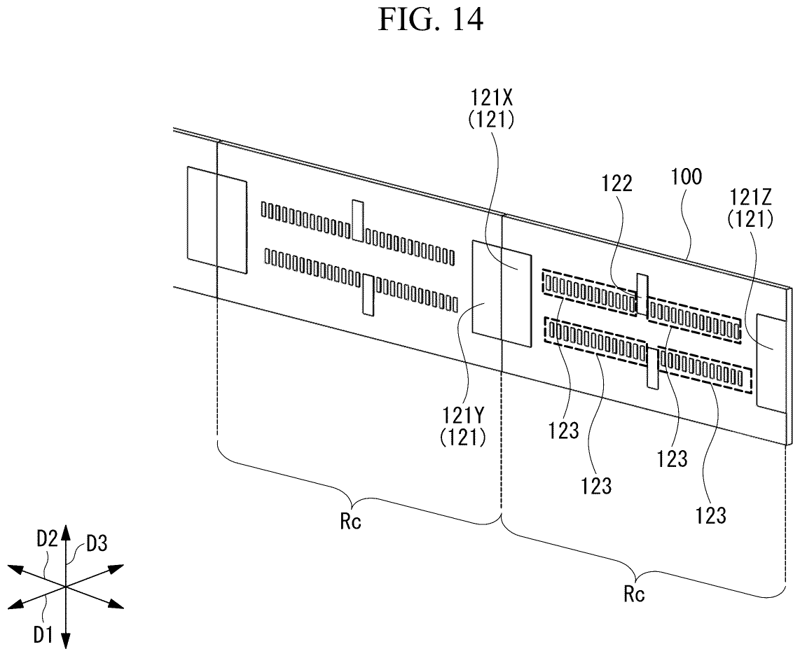

As illustrated in FIG. 14, the circuit board 100 is provided with a plurality of pads.

The pads include pads for power supply and pads used for other purposes than power supply (other-purpose pads 123). Further, the pads for power supply include first pads for power supply 121 and second pads for power supply 122.

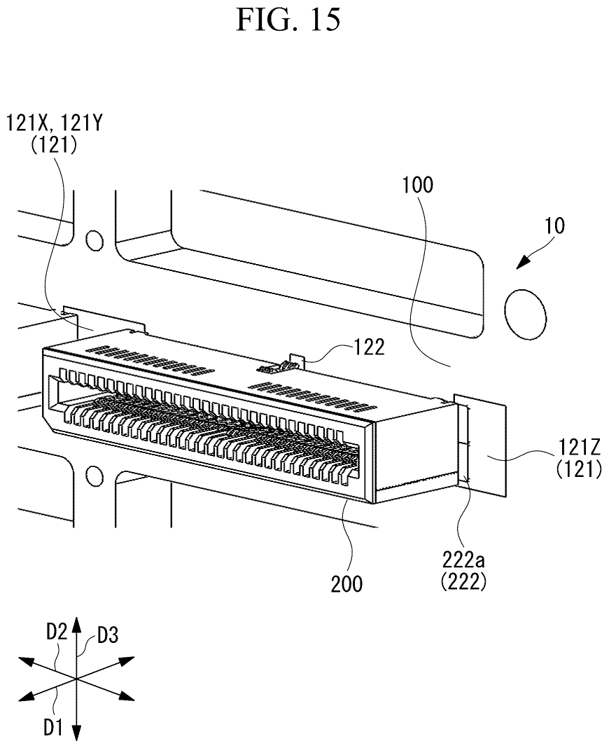

The first pads for power supply 121 are arranged on both sides in the second direction D2 in a region Rc on the circuit board 100 where a single connector 200 is mounted. The side tabs 222a of the bus bars 220 are bonded to the first pads for power supply 121 (see FIG. 15).

The second pads for power supply 122 are arranged (at a substantially intermediate position) between the first pad for power supply 121 (first pad for power supply 121Z) and the first pad for power supply 121 (first pad for power supply 121X) in the second direction D2. The mount parts 242 of the plurality of power supply pins 240 are bonded to the second pads for power supply 122 (see FIG. 15).

The other-purpose pads 123 include signaling pads for transmitting signals (high-speed signals and low-speed signals) and grounding pads serving as the reference potential. A plurality of other-purpose pads 123 are arranged in the second direction D2 between each first pad for power supply 121 and each second pad for power supply 122. The contact pins 230 are bonded (for example, connected by soldering) to the other-purpose pads 123.

The other-purpose pads 123 correspond to the contact pins 230 in a one-to-one manner. Thus, the plurality of other-purpose pads 123 are aligned with spacings (at the same pitch as that of the contact pins 230) in the second direction D2 and arranged over two levels in the third direction D3 so as to correspond to the first group G1 and the second group G2 of the contact pins 230. Further, the second pads for power supply 122 are also arranged over two levels in the third direction D3. On the other hand, each first pad for power supply 121 is not separated in the third direction D3.

These pads are provided in the first layer of the circuit board 100. Note that a solder resist layer (SR layer) may be layered on the surface of the first layer. However, portions to be bonded to the bus bars 220, the power supply pins 240, and the contact pins 230 (for example, the surfaces of the pads) are exposed in the SR layer.

The other-purpose pads 123 are electrically connected to layers other than the first layer through vias 130. In contrast, each pad for power supply arranged spaced in the second direction D2 is neither electrically connected to layers other than the first layer nor electrically connected to other pads through a via 130 or an inner layer wiring. However, a first pad for power supply 121 provided in the region Rc on the circuit board 100 on which one connector 200 is mounted (referred to as a “first pad for power supply 121X”) and another first pad for power supply 121 which is provided in the region Rc on the circuit board 100 on which another connector 200 adjacent to the one connector 200 is mounted in the second direction D2 and which is adjacent to the first pad for power supply 121X (referred to as a “first pad for power supply 121Y”) are integrally formed. Thus, the first pad for power supply 121X and the first pad for power supply 121Y are substantially a single pad shared by the adjacent two connectors 200. Thus, the first pad for power supply 121X will be electrically connected to the first pad for power supply 121Y.

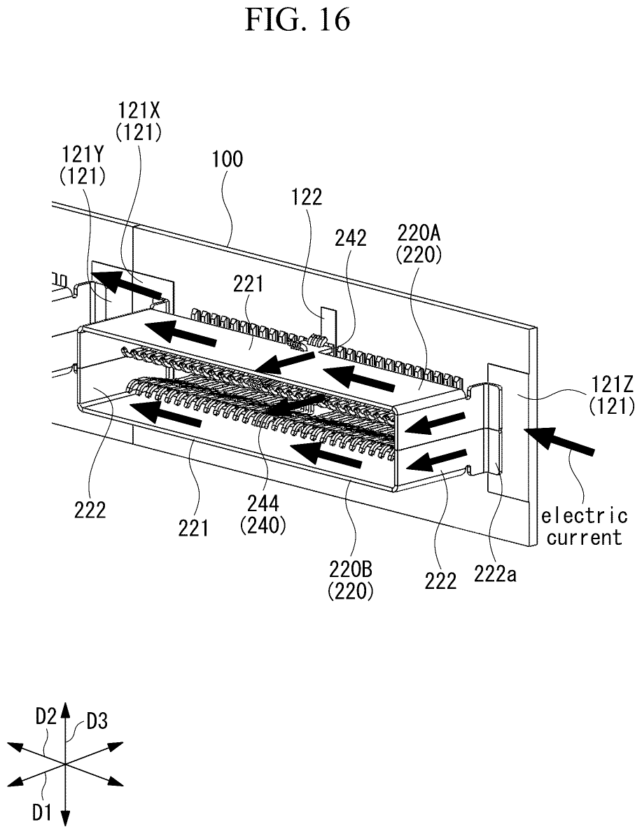

As illustrated in FIG. 16, the first pad for power supply 121 provided at the end in the second direction D2 of the circuit board 100 (referred to as a “first pad for power supply 121Z”) is externally supplied with electric power. For example, the electric current is 48A (ampere).

The connectors 200 are mounted on the circuit board 100 configured as described above. In this process, the side tabs 222a of the bus bars 220 are bonded to each first pad for power supply 121, the mount parts 242 of the plurality of power supply pins 240 are bonded to each second pad for power supply 122, and each contact pin 230 is bonded to each other-purpose pad 123.

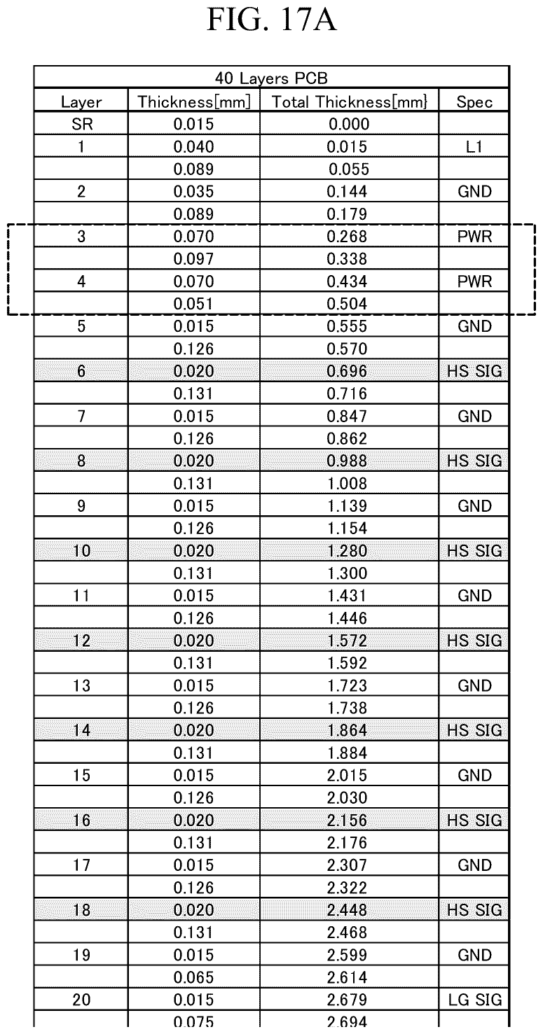

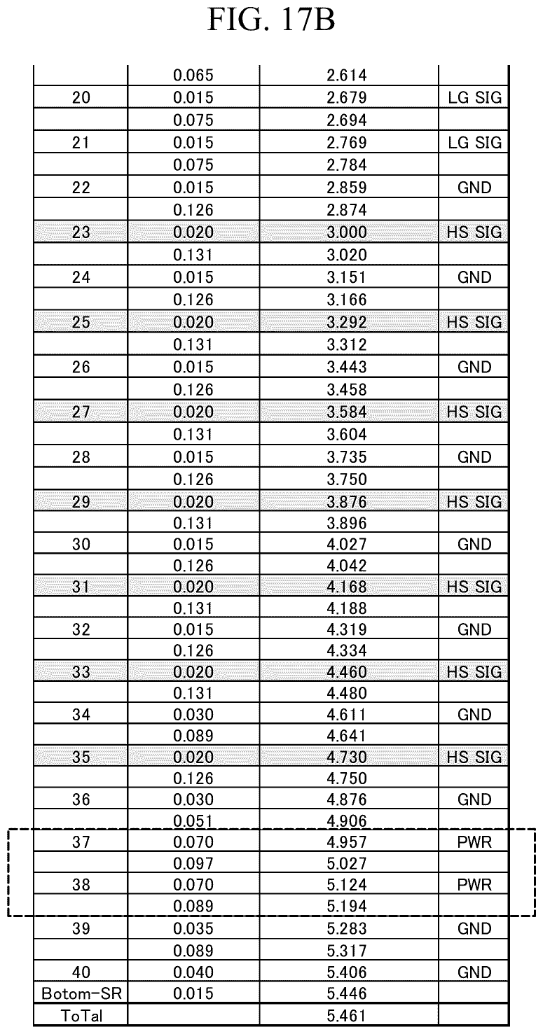

Since the power supply pins 240 and the bus bars 220 are integrated as described above, the bus bars 220 have a function of electrically connecting the first pads for power supply 121 and the power supply pins 240 to each other and a function of electrically connecting two first pads for power supply 121 (for example, the first pad for power supply 121Z and the first pad for power supply 121X) to each other within the region Rc on the circuit board 100 on which one connector 200 is mounted. In this case, the bus bars 220 will form a circuit/conductive line/wiring along the side faces of the connector body 210 (faces facing each other in the third direction D3 and faces facing each other in the second direction D2). Therefore, electric power supplied from the first pad for power supply 121 (for example, the first pad for power supply 121Z) via the side tab 222a flows through the bus bar side face 222 and the bus bar main face 221 to the power supply pins 240 and is then supplied to the module board 310. Further, electric power supplied from the first pad for power supply 121 (for example, the first pad for power supply 121Z) via one side tab 222a flows through one bus bar side face 222, the bus bar main face 221, and the other bus bar side face 222 to the other side tab 222a and is then supplied to another first pad for power supply 121 (for example, the first pad for power supply 121X). Note that the electric power supplied to the first pad for power supply 121X flows to the first pad for power supply 121Y and is then supplied to another connector 200. Thus, even when the power supply layer is omitted from the circuit board 100, the bus bars 220 serve as an alternative to the power supply layer. In other words, by providing the bus bars 220 to the connector 200, it is possible to omit the power supply layer from the circuit board 100. Further, since the power supply layer can be omitted from the circuit board 100, the board thickness of the circuit board 100 can be reduced (see the dashed line frames in FIG. 17A and FIG. 17B), and the reliability can be improved. Further, since the omission of the inner layer wiring for power supply from the inner layer of the circuit board 100 provides a corresponding amount of room in the inner layer, the flexibility in routing of other inner layer wirings used for other purposes than power supply (for signaling/for grounding) is improved.

Note that, when electric power is supplied through only the bus bars 220, the electric power is not supplied from the second pads for power supply 122 to the power supply pins 240, and the mount parts 242 of the power supply pins 240 are not required to be bonded to the second pads for power supply 122. Thus, the mount parts 242 may be omitted from the power supply pins 240.

However, in terms of more firmly bonding the connectors 200 to the circuit boards 100, the mount parts 242 of the power supply pins 240 may be bonded to the second pads for power supply 122.

Further, for example, when the module board 310 is inserted and extracted, force may act on the power supply pins 240 in any directions. In the state where such force acts, if the mount parts 242 of the power supply pins 240 are bonded to the second pads for power supply 122, the power supply pins can bear against such force. As a result, durability of the connector 200 against insertion and extraction of the module board 310 is improved.

### Modified Example 1

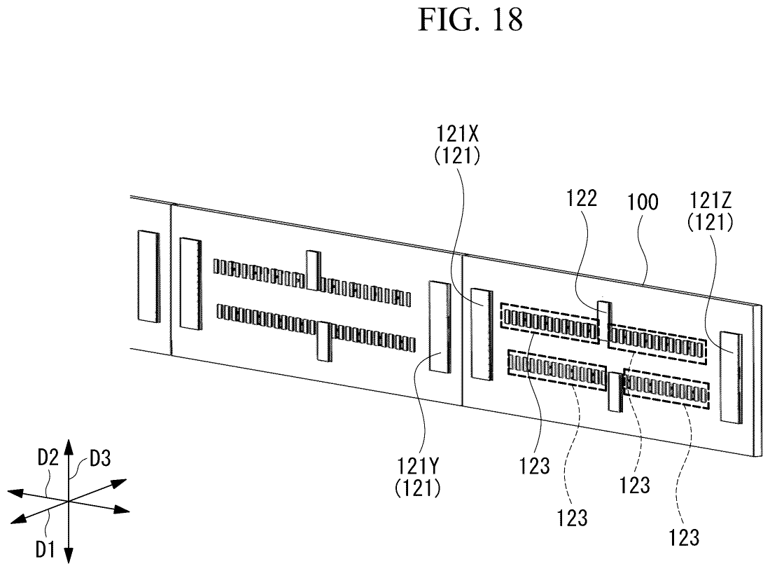

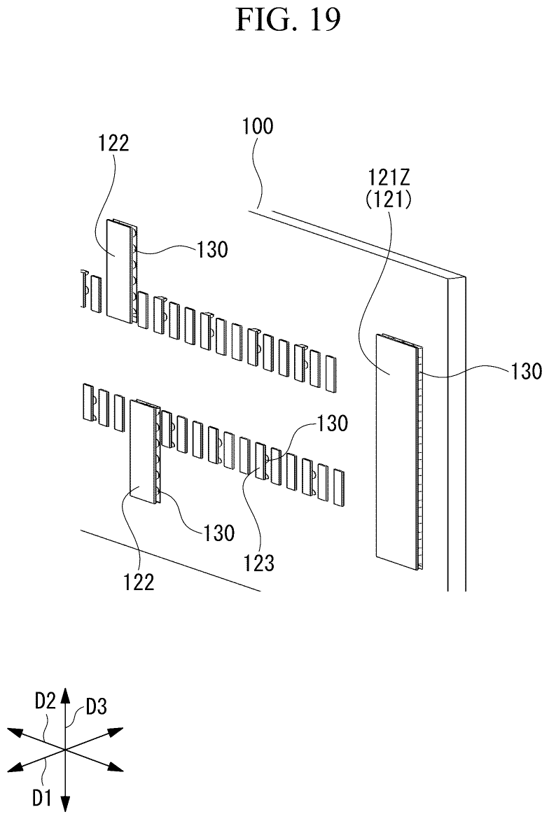

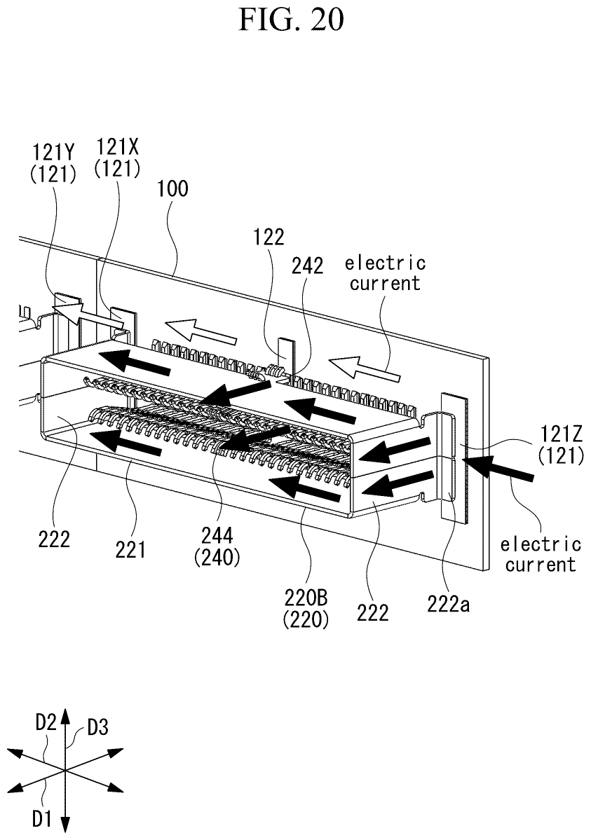

In addition to the bus bars 220, a layer other than the first layer of the circuit board 100 (for example, the third layer) may be used to supply electric power. For example, as illustrated in FIG. 18 and FIG. 19, pads for power supply and the third layer may be electrically connected through vias 130. In such a case, as illustrated in FIG. 20, electric power supplied from the first pad for power supply 121 (for example, the first pad for power supply 121Z) via the side tab 222a flows through the bus bar side face 222 and the bus bar main face 221 toward the power supply pins 240 and is then supplied to the module board 310, and also flows through the third layer and the second pads for power supply 122 toward the power supply pins 240 and is then supplied to the module board 310. Further, electric power supplied from one first pad for power supply 121 (for example, the first pad for power supply 121Z) via the side tab 222a flows through one bus bar side face 222, the bus bar main face 221, and the other bus bar side face 222 toward the other side tab 222a and is then supplied to another first pad for power supply 121 (for example, the first pad for power supply 121X), and also flows through the third layer and is then supplied to another first pad for power supply 121 (for example, the first pad for power supply 121X).

The electric current is caused to flow by using two paths (the bus bar 220 and the third layer of the circuit board 100), thereby the electric current flowing through the bus bars 220 is reduced, and the heat generated in the bus bars 220 is reduced. Furthermore, it is possible to suppress a rise in temperature of the connector 200 and the connector assembly 10 due to heat generation of the bus bars 220. However, the third layer is required to be provided in the inner layer of the circuit board 100. Nevertheless, it is sufficient to provide only one power supply layer in the inner layer of the circuit board 100, while it is conventionally required to provide four power supply layers in total for the inner layer of the circuit board 100. Also, the board thickness of the circuit board 100 can still be smaller than in the conventional one. Further, the power supply layer is provided at a position closer to the outermost layer than a signal layer, and thereby the via 130 connected to the power supply layer does not penetrate through the signal layer. Thus, the flexibility in routing the signal wiring in the signal layer is improved.

Note that, unlike a case where electric power is supplied only through the bus bars 220, electric power is supplied from the second pad for power supply 122 to the power supply pins 240 in the present modified example, and it is therefore required to bond the mount parts 242 of the power supply pins 240 to the second pads for power supply 122.

### Modified Example 2

The shape of the power supply pin 240 can be changed as appropriate as long as the power supply pin 240 can be in contact with the electrode for power supply of the module board 310, is connected to the bus bar main face 221, and can be bonded to the second pad for power supply 122 if necessary.

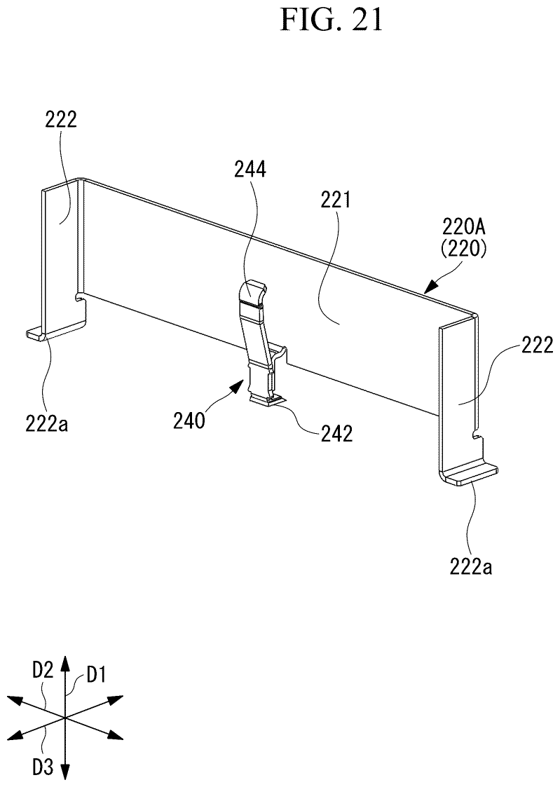

For example, as illustrated in FIG. 21, a plate material having its width direction in the second direction D2 may be used for the power supply pin 240. In such a case, for example, the power supply pin 240 is bonded by welding to the bus bar main face 221. Further, it is possible to optimize contact force of the module board 310 against the electrode for power supply by adjusting the plate thickness of the power supply pin 240.

### Modified Example 3

The dimension in the first direction D1 of the bus bar 220 can be changed as appropriate taking into consideration of the value of electric current flowing therethrough, the tolerable quantity of heat generation, or the impact of the bus bar 220 on electric characteristics (for example, crosstalk between channels). For example, this dimension in the first direction D1 of the bus bar 220 may be smaller than the dimension in the first direction D1 of the connector body 210 (for example, half or smaller).

Further, when the dimension in the first direction D1 of the bus bar 220 is reduced, the position in the first direction D1 of the bus bar 220 can be changed as appropriate within a range where the circumferential wall (exterior circumferential wall)/side face/surrounding of the connector body 210 is present.

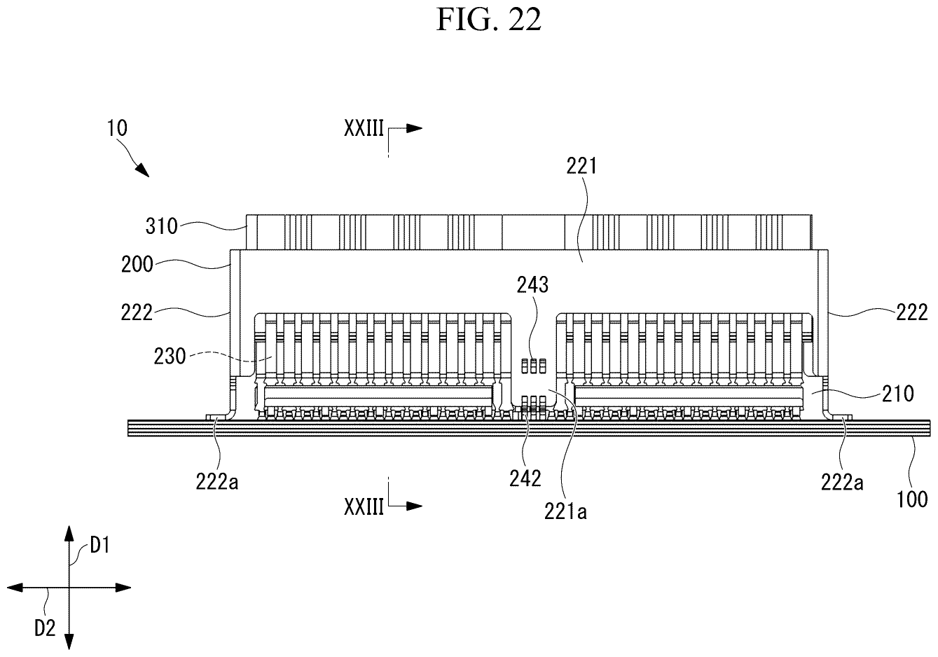

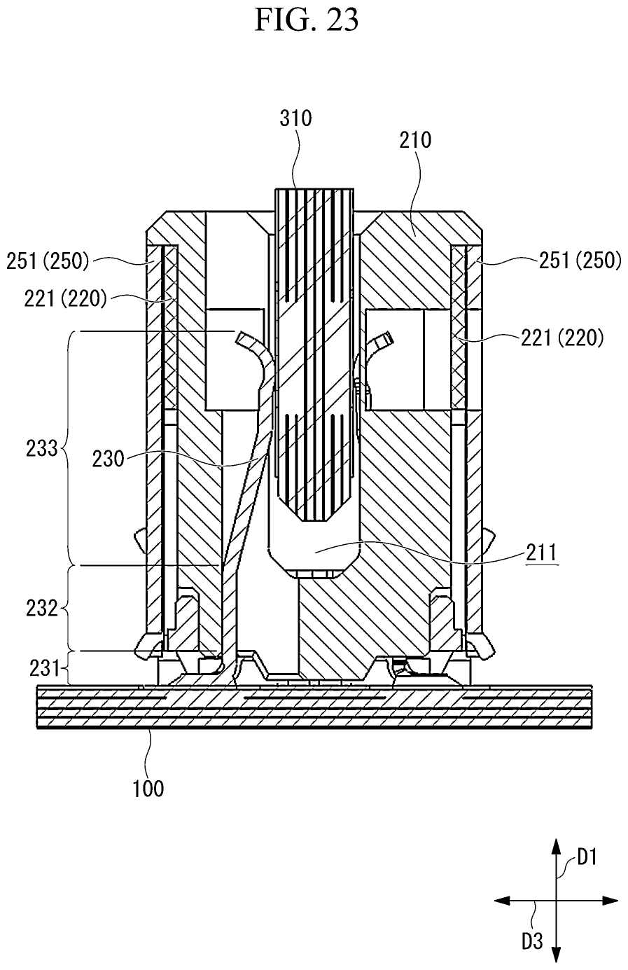

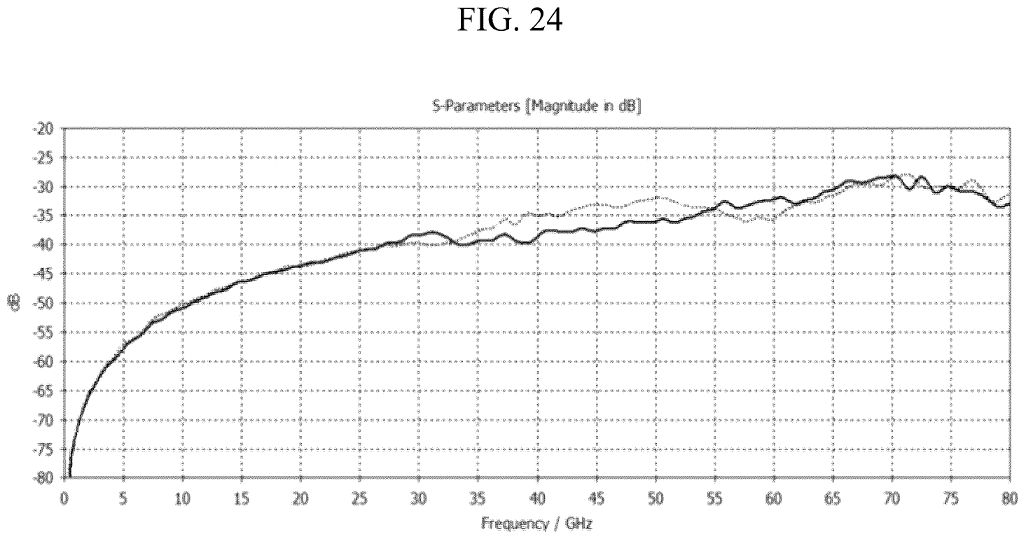

The dimension/position/range in the first direction D1 of the bus bar 220 will be described below in detail with reference to FIG. 22, FIG. 23, and FIG. 24. Note that, for easier understanding, a part of the contact pin 230 (a portion held by the connector body 210) illustrated in FIG. 22 is depicted as the connector body 210 being transparent.

As illustrated in FIG. 23, each contact pin 230 is a long, thin component elongated in the first direction D1. Each contact pin 230 is divided into three portions of a mount part 231, a holding part 232, and a contact part 233 from an end close to the circuit board 100 (hereafter, referred to as a “base end”) toward an end distant from the circuit board 100 (hereafter, referred to as a “distal end”).

The mount part 231 is a portion including an area to be bonded to the other-purpose pad 123 of the circuit board 100.

The holding part 232 is a portion held by the connector body 210. A protrusion 232a engaging into the slit 212 formed in the connector body 210 is formed in the holding part 232. The holding part 232 is elongated along the interior circumferential wall of the connector body 210 and elongated to be parallel to the first direction D1.

The contact part 233 is a portion including an area in contact with the module board 310. The contact part 233 is inclined so as to be spaced apart from the interior circumferential wall of the connector body 210 in the third direction D3. Specifically, each contact part 233 of the contact pin 230 included in the first group G1 is inclined toward the second group G2, and each contact part 233 of the contact pin 230 included in the second group G2 is inclined toward the first group G1.

It is preferable that the bus bar main face 221 be arranged in a range overlapped neither on the mount part 231 nor on the holding part 232 in the first direction D1 when viewed in the third direction D3. Thus, it is preferable that the dimension/position/range in the first direction D1 of the bus bar main face 221 be designed so as to be overlapped neither on the mount part 231 nor on the holding part 232 in the first direction D1. Note that, in addition to the range overlapped on the contact part 233, a range where the contact pin 230 is not present is also included in the range overlapped neither on the mount part 231 nor on the holding part 232.

With such design of the bus bar main face 221, the bus bar main face 221 is spaced apart from the contact pin 230 in the third direction D3, and the area of the bus bar main face 221 is reduced. Thus, radiation components of signals transmitted through the contact pin 230 are less likely to be transferred (less likely to be magnetically coupled) to the bus bar main face 221. This reduces a likelihood of radiation components of signals affecting adjacent channels via the bus bar main face 221 and can reduce crosstalk occurring between the channels.

FIG. 24 illustrates an example of simulation results in which the horizontal axis represents frequencies and the vertical axis represents crosstalk. The solid line represents crosstalk when the dimension/position/range in the first direction D1 of the bus bar main face 221 is within the range described above (see FIG. 22), and the dashed line represents crosstalk when the dimension/position/range in the first direction D1 of the bus bar main face 221 is substantially the same as the dimension in the first direction D1 of the connector body 210 (see FIG. 5). As can be seen from FIG. 24, the crosstalk of the present modified example represented by the solid line is smaller than the crosstalk of the comparative example (conventional example) represented by the dashed line in particular within a range from 35 GHz to 55 GHz.

Note that, although the expanded part 221a having the crimping hole 221b formed therein is provided on the bus bar main face 221 as illustrated in FIG. 22, the expanded part 221a is not required to be within the range described above. This is because the power supply pin 240 is present at the position corresponding to the expanded part 221a, the distance between channels (the contact pins 230) is larger than a predetermined pitch, and therefore, crosstalk between these channels is originally less likely to occur.

### Modified Example 4

Although the bus bar 220 is divided into the first bus bar 220A and the second bus bar 220B, the bus bar 220 is not necessarily required to be divided.

For example, a bus bar 220 may be produced as a single component, and the shape of the bus bar 220 may be cylindrical along the outer circumferential wall (exterior circumferential wall)/side face/surrounding of the connector body 210.

### Second Embodiment

The second embodiment of the present disclosure will be described.

Note that the same configuration as that of the first embodiment will be labeled with the same reference symbol, and the description thereof will be omitted.

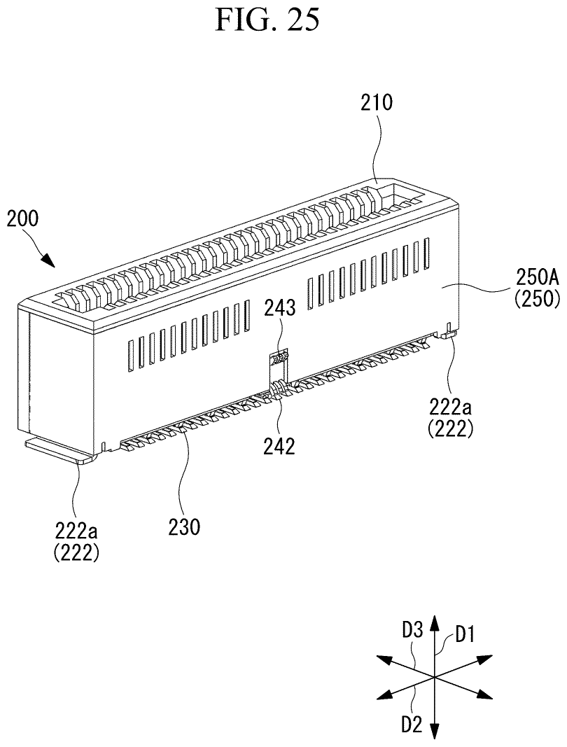

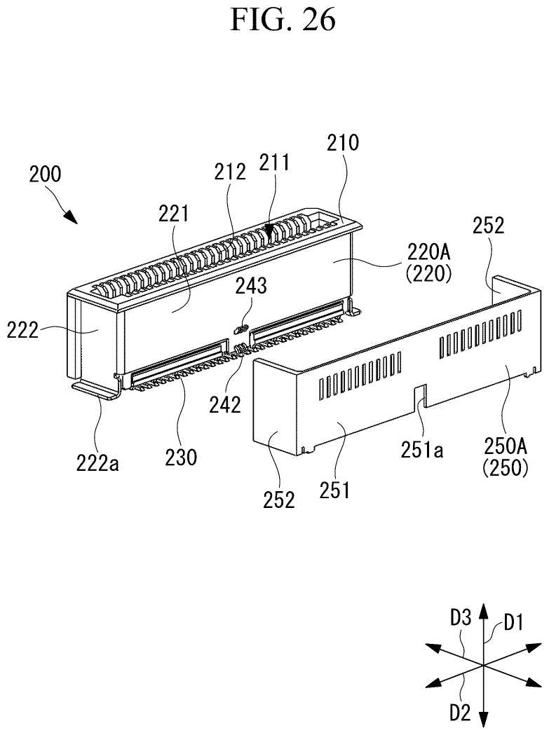

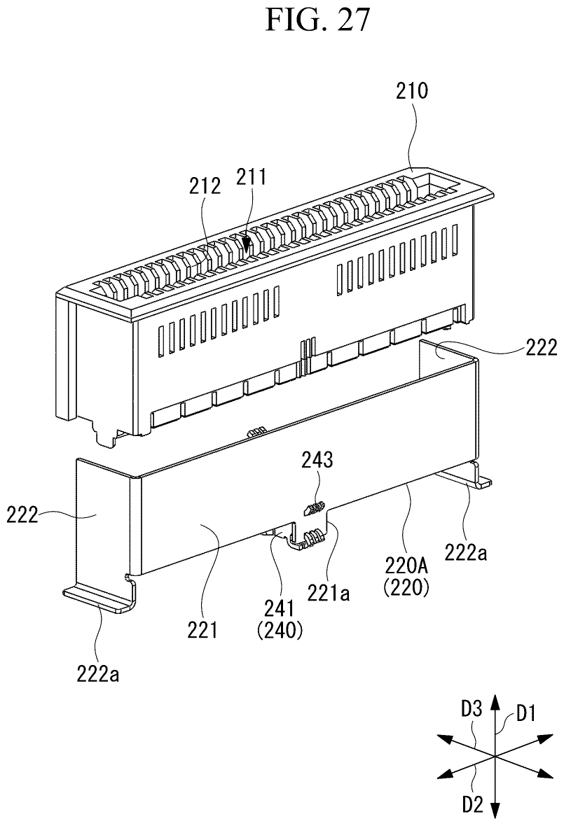

The connector 200 according to the first embodiment includes the first bus bar 220A and the second bus bar 220B as the bus bar 220. However, as illustrated in FIG. 25, FIG. 26, and FIG. 27, the second bus bar 220B (or the first bus bar 220A) can be omitted. This is a configuration that is made possible because two pin parts 244 are provided on one base 241. In the connector 200 according to the present embodiment, the second bus bar 220B is omitted, for example.

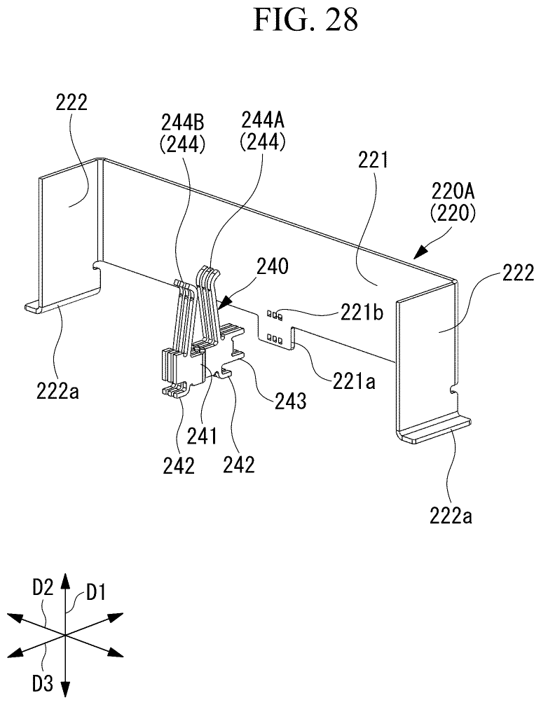

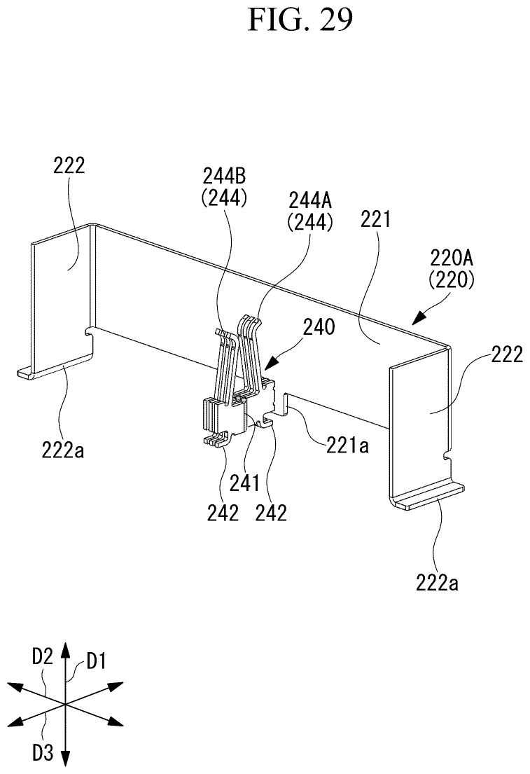

In such a case, as illustrated in FIG. 28 and FIG. 29, a plurality of power supply pins 240 are fixed to only the first bus bar 220A. Thus, the crimping protrusions 243 for fixing the base 241 to the second bus bar 220B can be omitted from the power supply pin 240.

Further, the second cover 250B for covering the second bus bar 220B can be omitted from the cover 250.

Modified example 1, Modified example 2, and Modified example 3 for the first embodiment can be employed to the present embodiment.

### Third Embodiment

The third embodiment of the present disclosure will be described.

Note that the same configuration as that of the first embodiment will be labeled with the same reference symbol, and the description thereof will be omitted.

### Connector

The connector 200 is a device for serving as a relay between the circuit board 100 and the module board 310 or electrically connecting the circuit board 100 and the module board 310 to each other.

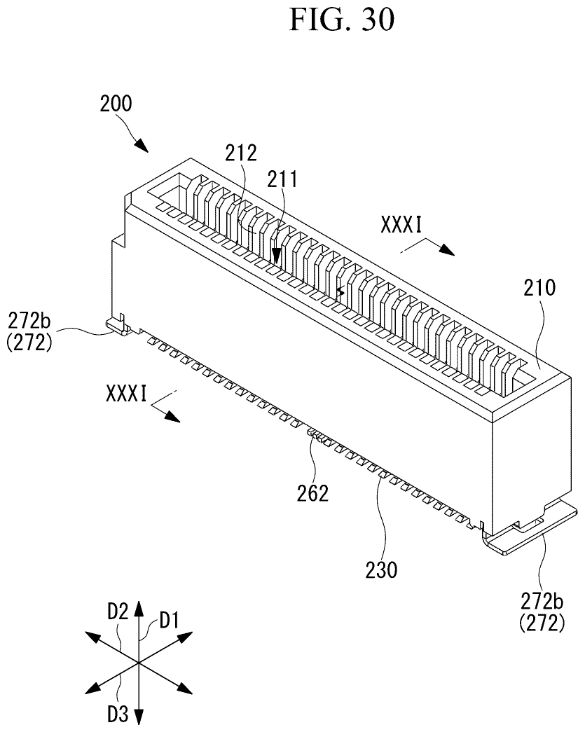

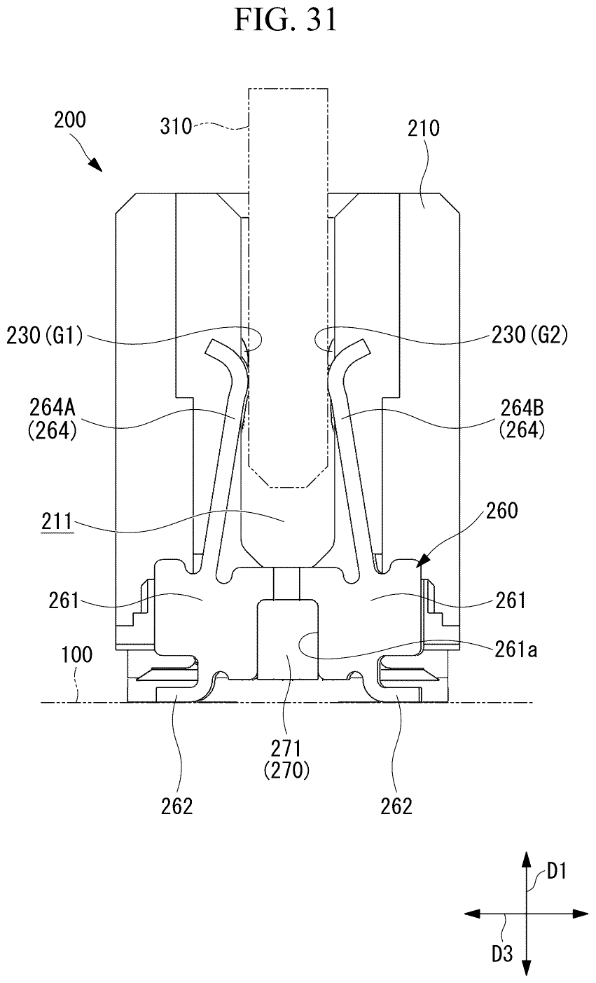

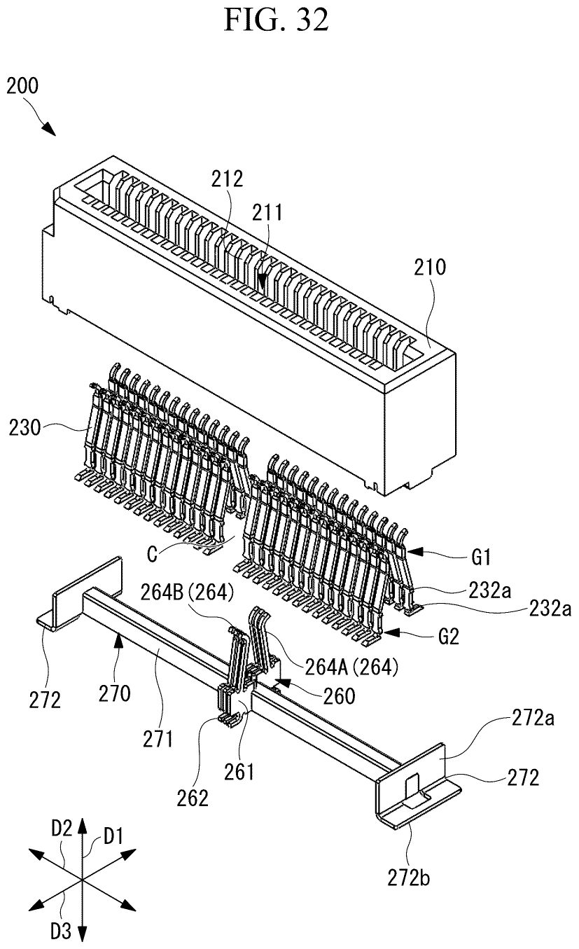

As illustrated in FIG. 30, FIG. 31, and FIG. 32, the connector 200 is substantially rectangular parallelepiped-shaped as a whole.

The connector 200 includes a connector body 210, a bus bar 270, a plurality of contact pins 230, and a plurality of power supply pins 260.

The connector body 210 is a substantially rectangular parallelepiped-shaped component.

The connector body 210 is formed of an insulating material (for example, a resin).

As illustrated in FIG. 30 and FIG. 31, slot 211 penetrating in the first direction D1 is formed in the central part of the connector body 210. The module board 310 is inserted into the slot 211.

As illustrated in FIG. 30, a plurality of slits 212 each extending in the first direction D1 are formed in the inner circumferential wall of the connector body 210 (the interior circumferential wall, the circumferential wall defining the slot 211). The contact pins 230 are press-fitted into these slits 212, respectively. Accordingly, the contact pins 230 are held by the connector body 210.

The bus bar 270 is arranged inside the connector body 210.

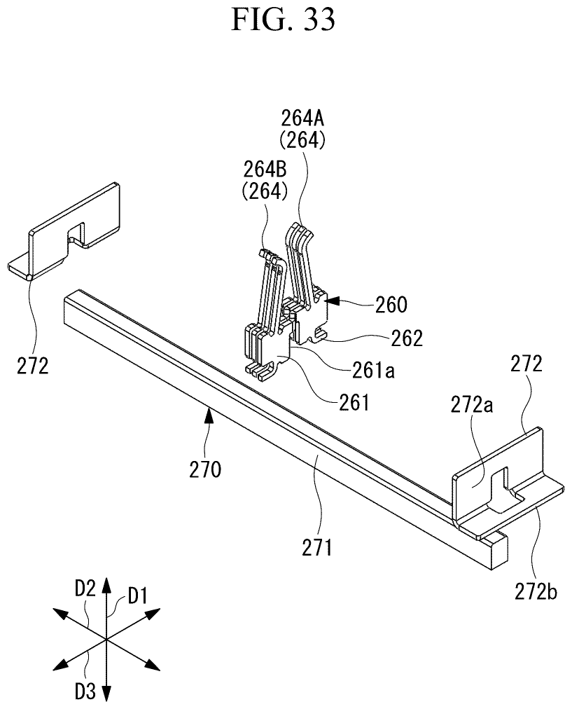

As illustrated in FIG. 33, the bus bar 270 includes a center part 271 and a plurality of side parts 272.

The center part 271 is a bar-like component elongated in the second direction D2.

For example, the sectional shape of the center part 271 (the cross section in a plane substantially orthogonal to the second direction D2) is rectangular. However, the sectional shape of the center part 271 may be other polygonal shapes, circular shapes, or the like.

The center part 271 is formed of a highly electrically conductive material (for example, a metal). Specifically, the center part 271 is formed of a copper-based material with plating (for example, nickel/gold plating) applied thereto.

Side parts 272 are provided on both ends in the second direction D2 of the center part 271.

Each side part 272 is a component having a side-face plate 272a and a mount tab 272b. For example, the side-face plate 272a and the mount tab 272b are integrally formed of a single member.

The side-face plate 272a is a plate-like portion having its thickness direction in the second direction D2.

The side-face plates 272a are connected to the ends in the second direction D2 of the center part 271. The side-face plate 272a of one side part 272 and the side-face plate 272a of the other side part 272 are arranged so as to face each other in the second direction D2.

Mount tabs 272b bent to be opened outward in the second direction D2 are provided on edges of the side-face plates 272a that face the circuit board 100 when the connector 200 is mounted on the circuit board 100. The mount tabs 272b are bonded (for example, connected by soldering) to pads for power supply of the circuit board 100.

As illustrated in FIG. 32, each of the plurality of contact pins 230 is a long, thin component elongated in the first direction D1.

Each contact pin 230 is formed of a highly electrically conductive and elastic material (for example, a metal). Specifically, each contact pin 230 is formed of a copper-based material with plating (for example, nickel/gold plating) applied thereto.

The contact pins 230 include signaling pins for transmitting signals (high-speed signals and low-speed signals) and grounding pins serving as the reference potential, but the contact pins 230 do not include pins for power supply.

A plurality of protrusions 232a are provided on a base end portion of the contact pin 230 (a portion near the mount part 231 bonded to the circuit board 100). Once these protrusions 232a engage into the slits 212 formed in the connector body 210, the contact pins 230 are held by the slits 212 (the connector body 210).

The plurality of contact pins 230 are formed of two groups (the first group G1 and the second group G2). In each group, the plurality of contact pins 230 are aligned with spacings (at a predetermined pitch) in the second direction D2. A clearance C for arranging the power supply pin 260 is provided (a wider spacing than the predetermined pitch is set) between the contact pins 230 located at the central part in the second direction D2. The first group G1 and the second group G2 are arranged so as to face each other in the third direction D3. However, each contact pin 230 included in the first group G1 and each contact pin 230 included in the second group G2 are shifted from each other by a half pitch (half of the predetermined pitch) in the second direction D2. The module board 310 of the optical module 300 is inserted into the clearance between the first group G1 and the second group G2. Each contact pin 230 included in each group then comes into contact with other-purpose electrodes of the inserted module board 310 in a one-to-one manner.

As illustrated in FIG. 31, FIG. 32, and FIG. 33, the power supply pin 260 is a component having a base 261, a plurality of mount parts 262, and a plurality of pin parts 264. The base 261, the plurality of mount parts 262, and the plurality of pin parts 264 are integrally formed of a single member, for example.

Each power supply pin 260 is formed of a highly electrically conductive and elastic material (for example, a metal). Specifically, the power supply pin 260 is formed of a copper-based material with plating (for example, nickel/gold plating) applied thereto.

The base 261 is a plate-like portion having its thickness direction in the second direction D2.

A cutout 261a is formed in the base 261. The cutout 261a is formed recessed in the first direction D1 from an edge of the base 261 facing the circuit board 100 when the connector 200 is mounted on the circuit board 100. The center part 271 of the bus bar 270 is inserted into this cutout 261a. Therefore, the shape of the cutout 261a is adapted to the shape of the center part 271 of the bus bar 270.

The base 261 is connected (for example, bonded by welding) to the center part 271 of the bus bar 270 inserted into the cutout 261a.

Each mount part 262 is a portion extending in the first direction D1 from an edge of the base 261 and then bent to be opened outward in the third direction D3, the edge of the base 261 facing the circuit board 100 when the connector 200 is mounted on the circuit board 100. These mount parts 262 are bonded (for example, connected by soldering) to pads for power supply of the circuit board 100.

Each pin part 264 is a long, thin portion elongated in the first direction D1 extending in the first direction D1 from the edge of the base 261 facing the slot 211 (the edge located opposite to the edge of the base 261 facing the circuit board 100 when the connector 200 is mounted on the circuit board 100 or the edge facing the module board 310 side when the module board 310 is inserted into the connector 200). For example, the pin part 264 has a shape similar to the shape of the contact pin 230. Two pin parts 264 are provided on one base 261. The first pin part 264A and the second pin part 264B are arranged so as to face each other in the third direction D3 while being shifted from each other in the second direction D2. Because the two pin parts 264 shifted in the second direction D2 are provided on one base 261, the portion of the base 261 where the first pin part 264A is provided and the portion of the base 261 where the second pin part 264B is provided are shifted from each other in the second direction D2, and these portions are connected smoothly to each other.

The plurality of (for example, three) power supply pins 260 configured as described above are overlapped to configure the group of power supply pins 260. Such a group of power supply pins 260 is arranged in the clearance C provided between the contact pins 230 of the first group G1 and the clearance C provided between the contact pins 230 of the second group G2. In this state, each pin part 264 of each power supply pin 260 is arranged to be continuous to the contact pins 230 aligned in the second direction D2.

As illustrated in FIG. 31, the module board 310 of the optical module 300 is inserted into the clearance between the set of the plurality of first pin parts 264A and the set of the plurality of second pin parts 264B where both the sets are arranged so as to face each other in the third direction D3. Each pin part 264 then comes into contact with the electrodes for power supply of the inserted module board 310. However, respective pin parts 264 are not required to correspond to electrodes for power supply in a one-to-one manner, and it is at least required that one or more pin parts 264 be in contact with one electrode for power supply.

In the connector 200 configured as described above, the bus bar 270 is accommodated inside the connector body 210.

Specifically, as illustrated in FIG. 31, the center part 271 of the bus bar 270 is arranged in the clearance between the first group G1 and the second group G2 of the contact pins 230 facing each other in the third direction D3. Further, the center part 271 of the bus bar 270 is arranged at a position at which the center part 271 is in contact neither with the circuit board 100 nor with the module board 310 when the connector 200 is mounted on the circuit board 100 and the optical module 300 is inserted into the connector 200. Note that the base 261 of the power supply pin 260 connected to the bus bar 270 is also arranged at a position at which the base 261 is not in contact with the module board 310 when the optical module 300 is inserted into the connector 200.

Further, the side parts 272 of the bus bar 270 are inserted into the walls of the connector body 210 facing each other in the second direction D2.

In such a way, the bus bar 270 is not exposed from the connector 200 in appearance, and thus the operator is unable to easily touch the bus bar 270. This avoids a risk that the operator receives an electric shock due to electric current flowing through the bus bar 270, thereby ensuring safety.

### Flow of Electric Current

The mount tab 272b of the side part 272 of the bus bar 270 is bonded to each first pad for power supply 121.

Since the power supply pins 260 and the bus bar 270 are integrated as described above, the bus bar 270 has a function of electrically connecting the first pads for power supply 121 and the power supply pins 260 to each other and a function of electrically connecting two first pads for power supply 121 to each other within the region Rc on the circuit board 100 on which one connector 200 is mounted. In this case, the bus bar 270 will form a circuit/conductive line/wiring extending in the second direction D2 inside the connector body 210. Therefore, electric power supplied from the first pad for power supply 121 (for example, the first pad for power supply 121Z) via the side part 272 flows through the center part 271 toward the power supply pins 260 and is then supplied to the module board 310. Further, electric power supplied from the first pad for power supply 121 (for example, the first pad for power supply 121Z) via one side part 272 flows through the center part 271 toward the other side part 272 and is then supplied to another first pad for power supply 121 (for example, the first pad for power supply 121X). Note that the electric power supplied to the first pad for power supply 121X flows to the first pad for power supply 121Y and is then supplied to another connector 200. Thus, even when the power supply layer is omitted from the circuit board 100, the bus bar 270 serves as an alternative to the power supply layer. In other words, by providing the bus bar 270 to the connector 200, it is possible to omit the power supply layer from the circuit board 100. Further, since the power supply layer can be omitted from the circuit board 100, the board thickness of the circuit board 100 can be reduced. Further, since inner layer wirings for power supply can be omitted from the inner layer of the circuit board 100, the flexibility in routing inner layer wirings used for other purposes than power supply (for signaling/for grounding) is improved.

Note that, when electric power is supplied through only the bus bar 270, the electric power is not supplied from the second pads for power supply 122 to the power supply pins 260, and the mount parts 262 of the power supply pins 260 are not required to be bonded to the second pads for power supply 122. Thus, the mount parts 262 may be omitted from the power supply pins 260.

However, in terms of more firmly bonding the connectors 200 to the circuit boards 100, the mount parts 262 of the power supply pins 260 may be bonded to the second pads for power supply 122.

Further, for example, when the module board 310 is inserted and extracted, force may act on the power supply pins 260 in any directions. In the state where such force acts, if the mount parts 262 of the power supply pins 260 are bonded to the second pads for power supply 122, the power supply pins 260 can bear against such force. As a result, durability of the connector 200 against insertion and extraction of the module board 310 is improved.

Modified example 1 and Modified example 2 for the first embodiment can be employed to the present embodiment.

### Fourth Embodiment

The fourth embodiment of the present disclosure will be described.

Note that the same configuration as that of the first embodiment will be labeled with the same reference symbol, and the description thereof will be omitted.

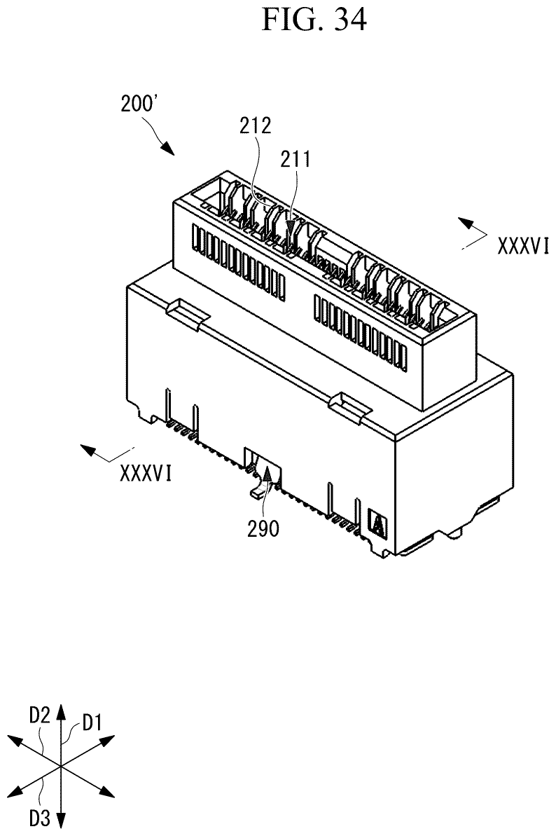

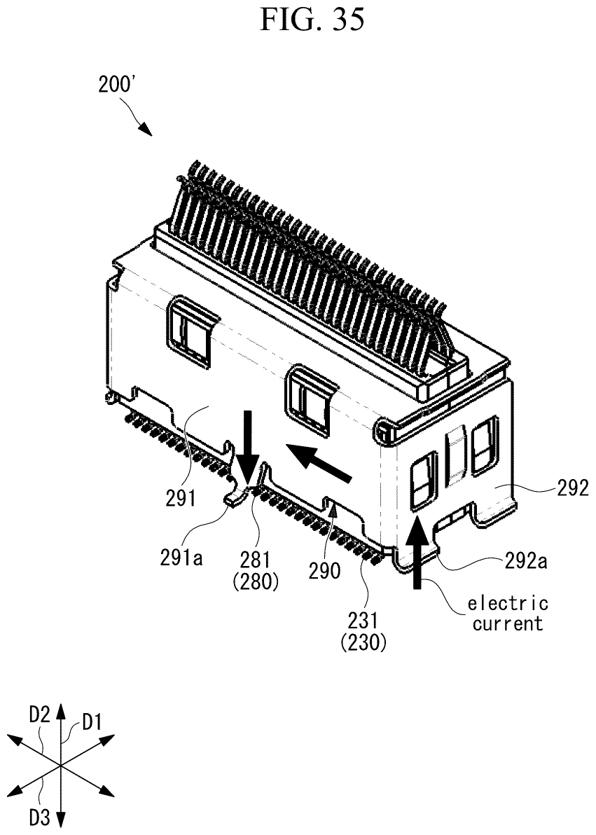

As illustrated in FIG. 34 and FIG. 35, a connector 200′ of the present embodiment has a plurality of power supply pins 280.

The shape of each power supply pin 280 is the same as the shape of the contact pin 230. In other words, this eliminates the need for differentiating the shape of the power supply pins 280 from the shape of another contact pin 230. This makes it possible to commonize the components.

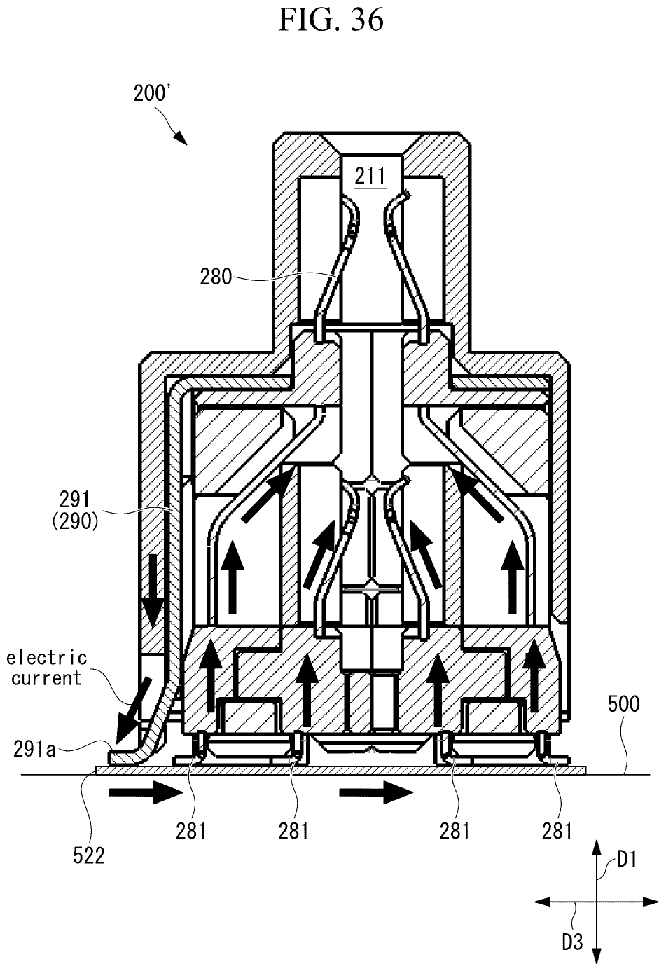

As illustrated in FIG. 36, mount parts 281 corresponding to the base end portions of the power supply pins 280 are bonded to a second common pad for power supply 522 of a printed circuit board 500 (hereafter, referred to as “circuit board 500”).

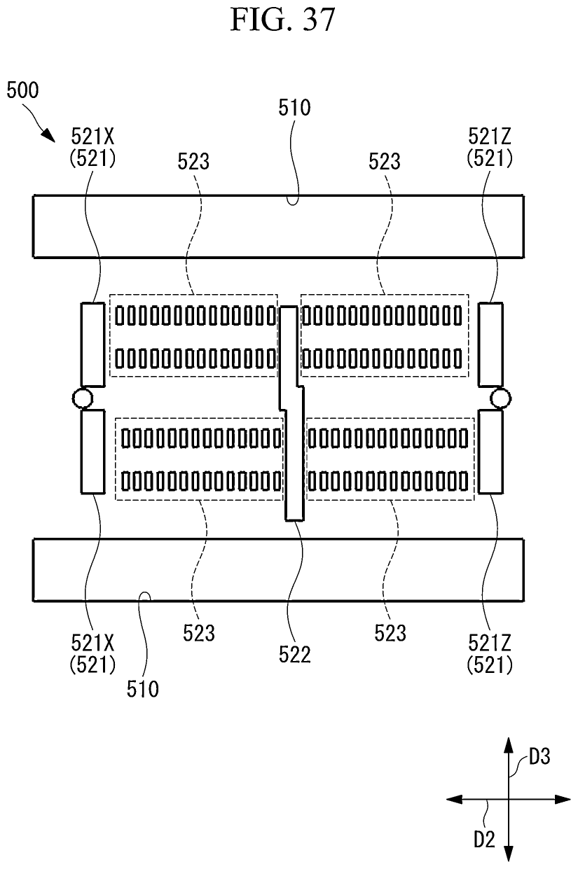

As illustrated in FIG. 37, the circuit board 500 has basically the same configuration as the circuit board 100 (see FIG. 14, FIG. 15, and the like). Specifically, the circuit board 500 has vent openings 510, first pads for power supply 521, and other-purpose pads 523.

In the case of FIG. 37, however, the other-purpose pads 523 are aligned in four levels in the third direction D3. Note that the number of levels of the other-purpose pads 523 may be two as with the circuit board 100.

The circuit board 500 is provided with a second common pad for power supply 522 instead of the second pads for power supply 122 as seen in the circuit board 100.

In contrast to the other-purpose pads 523 aligned in four levels in the third direction D3, the second common pad for power supply 522 is a single pad continuous in the third direction D3. The length of the second common pad for power supply 522 along the third direction D3 is longer than the length from the first-level other-purpose pad 523 to the fourth-level other-purpose pad 523.

However, the shape of the second common pad for power supply 522 is not necessarily required to be a straight extending in the third direction D3 and may be modified as appropriate in accordance with the arrangement of the other-purpose pads 523. Furthermore, the second common pad for power supply 522 may be divided, and the divided second common pads 522 may be connected via an inner layer of the circuit board 500.

As illustrated in FIG. 36, the mount parts 281 of all the power supply pins 280 are bonded to the second common pad for power supply 522. Furthermore, a bus bar 290 is bonded to the second common pad for power supply 522.

As illustrated in FIG. 35 and FIG. 36, the bus bar 290 has, for example, one bus bar main face 291 and two bus bar side faces 292.

Side tabs 292a bonded to the first pads for power supply 521 (521X, 521Z) are provided to an edge of each bus bar side face 292 (the edge facing the circuit board 500) as with the first embodiment.

A center tab 291a extending in the first direction D1 and then bent to be opened outward in the third direction D3 is provided at substantially the center in the second direction D2 of an edge of the bus bar main face 291 (the edge facing the circuit board 500).

The center tab 291a is bonded to the second common pad for power supply 522 of the circuit board 500. This allows the bus bar 290 to be electrically connected to the second common pad for power supply 522.

When all the power supply pins 280 are connected to the second common pad for power supply 522 and the bus bar 290 is connected to the second common pad for power supply 522, the bus bar 290 and the power supply pins 280 will be electrically connected to each other via the second common pad for power supply 522.

Accordingly, as illustrated in FIG. 36, electrical power can be indirectly supplied from the bus bar 290 to the power supply pins 280 via the second common pad for power supply 522.

### Modified Example 4

The bus bar 290 may have two bus bar main faces 291 and two bus bar side faces 292.

In such a case, the number of center tabs 291a is two. Each center tab 291a is bonded to the second common pad for power supply 522 of the circuit board 500.

### Modified Example 5

The power supply pins 280 adjacent to each other in the second direction D2 may be integrated. This increases the dimension in the second direction (width dimension) of the power supply pins 280. Since a larger width dimension of the power supply pins 280 reduces the resistance value of the power supply pins 280, it is possible to reduce the quantity of heat generation of the power supply pins 280 for the same electrical current value and increase the maximum electrical current value that can be tolerated by the power supply pins 280. Further, because the width dimension of the power supply pins 280 is increased, the heat dissipation performance of the power supply pins 280 is improved.

Modified example 1 and Modified example 3 for the first embodiment can be employed to the present embodiment.

### LIST OF REFERENCE SYMBOLS

10 connector assembly
100 printed circuit board (circuit board)
110 vent opening
121 (121X, 121Y, 121Z) first pad for power supply
122 second pad for power supply
123 other-purpose pad
130 via
200, 200′ connector
210 connector body
211 slot
212 slit
220 (220A, 220B) bus bar
220A first bus bar
221 bus bar main face
221a expanded part
221b crimping hole
222 bus bar side face
222a side tab
220B second bus bar
221 bus bar main face
221a expanded part
221b crimping hole
222 bus bar side face
222a side tab
230 contact pin
231 mount part
232 holding part
232a protrusion
233 contact part
240 power supply pin
241 base
242 mount part
243 crimping protrusion
244 pin part
244A first pin part
244B second pin part
250 (250A, 250B) cover
250A first cover
251 cover main face
251a cutout
252 cover side face
250B second cover
251 cover main face
252 cover side face
260 power supply pin
26 base
261a cutout
262 mount part
264 pin part
264A first pin part
264B second pin part
270 bus bar
271 center part
272 side part
272a side face plate
272b mount tab
280 power supply pin
281 mount part
290 bus bar
291 bus bar main face
291a center tab
292 bus bar side face
292a side tab
300 optical module (external module)
310 module board
500 printed circuit board (circuit board)
510 vent opening
521 (521X, 521Z) first pad for power supply
522 second common pad for power supply
523 other-purpose pad
C clearance
G1 first group
G2 second group
Rc region

What is claimed is:

1. A connector which is mounted on a circuit board and into which a module board of an external module is inserted in a first direction,
the circuit board including a plurality of pads for power supply that are arranged spaced apart from each other in a second direction substantially orthogonal to the first direction, and the module board including a plurality of electrodes for power supply,
the connector comprising:
a connector body into which the module board is inserted;
one or a plurality of power supply pins accommodated inside the connector body and being in contact with the plurality of electrodes for power supply of the module board; and
at least one bus bar,
wherein the bus bar is connected to the one or plurality of power supply pins, and is connected to the plurality of pads for power supply that are arranged spaced apart from each other in the second direction.

2. The connector according to claim 1,
wherein the connector body includes
two second side faces facing each other in the second direction, and
two third side faces facing each other in a third direction orthogonal to both the first direction and the second direction,
wherein the bus bar includes
a bus bar main face overlapped on the third side face, and
two bus bar side faces connected to the bus bar main face and overlapped on each of the second side faces, and
wherein each of the bus bar side faces is connected to a corresponding pad for power supply of the pads for power supply.

3. The connector according to claim 2,
wherein the circuit board includes a plurality of other-purpose pads used for other purposes than power supply that are aligned in the second direction, and
wherein the module board includes a plurality of other-purpose electrodes used for other purposes than power supply,
wherein the connector further comprises: a plurality of contact pins accommodated inside the connector body, elongated in the first direction, and being in contact with the other-purpose electrodes of the module board,
wherein each of the contact pins includes
a mount part bonded to the other-purpose pads of the circuit board,
a holding part held by interior circumferential walls of the connector body, and
a contact part inclined so as to be spaced apart from the interior circumferential walls of the connector body and including a contact area in contact with the module board, and
wherein the bus bar main face viewed in the third direction is arranged in a range overlapped neither on the mount part nor on the holding part in the first direction.

4. The connector according to claim 2,
wherein the number of bus bars is two, and
wherein the one or plurality of power supply pins are fixed to two bus bar main faces facing each other in the third direction.

5. The connector according to claim 2,
wherein the number of bus bars is one, and
wherein the one or plurality of power supply pins are fixed to one bus bar main face.

6. The connector according to claim 2,
wherein each of the bus bar side faces of the bus bar includes a tab-like side tab, and
wherein the side tab is bonded to each of the pads for power supply of the circuit board.

7. The connector according to claim 2 further comprising at least one cover covering the bus bar.

8. The connector according to claim 7,
wherein the number of covers is the same as the number of bus bars, and
wherein the cover includes
a cover main face overlapped on the bus bar main face, and
two cover side faces connected to the cover main face and each overlapped on a corresponding bus bar side face of the bus bar side faces.

9. The connector according to claim 8,
wherein the number of covers is two,
wherein the two covers are arranged facing each other in the third direction, and
wherein the cover side faces of one of the covers are each bonded to a corresponding cover side face of the cover side faces of the other of the covers so as to integrate the two covers.

10. The connector according to claim 1,
wherein the module board includes a plurality of other-purpose electrodes used for other purposes than power supply,
wherein the connector further comprises: a first pin group and a second pin group accommodated inside the connector body,
wherein the first pin group and the second pin group each have a plurality of contact pins each elongated in the first direction and being in contact with the other-purpose electrodes of the module board,
wherein the first pin group is configured with the plurality of contact pins being aligned in the second direction,
wherein the second pin group is configured with the plurality of contact pins being aligned in the second direction,
wherein the first pin group and the second pin group are arranged facing each other in a third direction orthogonal to both the first direction and the second direction,
wherein the bus bar includes
a center part arranged between the first pin group and the second pin group and elongated in the second direction, and
two side parts connected to both ends in the second direction of the center part, and
wherein each of the side parts is connected to a corresponding pad for power supply of the pads for power supply.

11. The connector according to claim 10, wherein when the connector is mounted on the circuit board and the module board is inserted into the connector, the center part is located between the first pin group and the second pin group facing each other in the third direction.

12. A connector assembly comprising:
the connector according to claim 1; and
the circuit board on which the connector is mounted,
wherein the circuit board includes the plurality of pads for power supply that are arranged spaced apart from each other in the second direction.

13. The connector assembly according to claim 12,
wherein the circuit board includes
an inner layer including a plurality of signal layers and one power supply layer,
an outermost layer covering the surface of the inner layer, and
a plurality of vias,
wherein the pads for power supply are connected to the power supply layer of the inner layer through the vias, and
wherein the power supply layer is provided at a position closer to the outermost layer than the signal layers.

14. The connector assembly according to claim 12 further comprising the connector according to claim 1, the connector including a first connector and a second connector,
wherein the first connector and the second connector are adjacent to each other in the second direction, and
wherein the bus bar of the first connector and the bus bar of the second connector are connected to the pads for power supply provided between and shared by the first connector and the second connector.

15. The connector according to claim 1, wherein the bus bar is indirectly connected to the one or plurality of power supply pins.

16. A connector assembly comprising:
the connector according to claim 15; and
the circuit board on which the connector is mounted,
wherein the one or plurality of power supply pins are connected to pads provided on the circuit board, and
wherein the bus bar is connected to the pads to which the one or plurality of power supply pins are connected.
